(19) United States
(12) Patent Application Publication
(10) Pub. No.: US 2024/0344628 A1
(43) Pub. Date: Oct. 17, 2024

(54) FLUID FLOW COMPONENTS AND SYSTEM INCORPORATING SAME

(71) Applicant: Ichor Systems, Inc., Fremont, CA (US)

(72) Inventors: Stephen Carson, Woodstock, NY (US); Michael Vogtmann, Templeton, CA (US)

(21) Appl. No.: 18/612,705

(22) Filed: Mar. 21, 2024

Related U.S. Application Data
(60) Provisional application No. 63/492,597, filed on Mar. 28, 2023.

(51) Int. Cl. F16K 31/08; F16K 15/02; H01L 21/67

(52) U.S. Cl. CPC F16K 31/084; F16K 15/023; H01L 21/67017

(57) ABSTRACT

Apparatuses for controlling fluid flow are important components for delivering process fluids for semiconductor fabrication. These apparatuses for controlling fluid flow frequently rely on fluid flow components which incorporate check valves to prevent reverse flow of fluids within the apparatuses for controlling fluid flow. The check valves make use of magnetic fields to enable biasing of a closure member against a seat without the need for mechanical biasing elements such as springs. These magnetic fields may be generated by one or more magnets, improving a wide range of operating parameters.

### CROSS-REFERENCE TO RELATED APPLICATIONS

This application claims the benefit of U.S. Provisional Application 63/492,597, filed Mar. 28, 2023, which is incorporated herein by reference in its entirety.

### BACKGROUND OF THE INVENTION

Flow control has been one of the key technologies in semiconductor chip fabrication. Apparatuses for controlling fluid flow are important for delivering known flows of process fluids for semiconductor fabrication and other industrial processes. Such devices are used to measure and accurately control the flow of fluids for a variety of applications. This control relies on components incorporating check valves to enable reliable prevention and control of reverse flows of fluids within a system. Such systems may incorporate components having one or more check valves to create apparatuses for controlling fluid flow and fluid delivery modules comprising one or more apparatuses for controlling fluid flow.

As the technology of chip fabrication has improved, so has the demand on the apparatuses for controlling flow. Semiconductor fabrication processes increasingly require increased performance, including more accurate measurements, lower equipment costs, improved transient response times, and more consistency in timing in the delivery of fluids. In order to improve performance of flow control equipment, improved components incorporating check valves are desired.

### SUMMARY OF THE INVENTION

The present technology is directed to a component incorporating a check valve for use in a mass flow controller or other gas or liquid delivery device. One or more of these gas or liquid delivery devices may be used in a wide range of processes such as semiconductor chip fabrication, solar panel fabrication, etc.

In one implementation, the invention is a fluid flow component having a housing and a closure member. The housing has an inlet, an outlet, a cavity, a seat, and a flow path. A longitudinal axis extends along the cavity. The seat is located within the cavity. The flow path extends from the inlet to the cavity and from the cavity to the outlet. The closure member is slidably movable within the cavity of the housing. The closure member is configured to engage the seat to prevent fluid flow through the flow path in a reverse direction. A magnetic field biases the closure member into contact with the seat.

In another implementation, the invention is a system for processing articles. The system has a first fluid flow component, a second fluid flow component, and a seal. The first fluid flow component has a housing and a closure member. The housing has an inlet with a first port, the first port having a seal cavity. The outlet has a second port, the second port having a seal cavity. The housing further has a cavity with a longitudinal axis extending along the cavity and a seat within the cavity. A flow path extends from the inlet to the cavity and from the cavity to the outlet. The closure member is slidably movable within the cavity of the housing, the closure member configured to engage the seat to prevent fluid flow through the flow path in a reverse direction. The second fluid flow component has a first port and a second port, a flow path extending from the first port to the second port. Each of the first and second port has a seal cavity. When the second port of the second fluid flow component is aligned with the first port of the first fluid flow component, the seal is located within the seal cavity of the second port of the second fluid flow component and the seal cavity of the first port of the first fluid flow component. A magnetic field biases the closure member into contact with the seat.

In yet another implementation, the invention is a fluid flow component. The fluid flow component has a housing, a stop member, and a closure member. The housing has an inlet, an outlet, and a cavity. A longitudinal axis extends along the cavity. A seat is located within the cavity and a flow path extends from the inlet to the cavity and from the cavity to the outlet. The stop member has a first magnet. The closure member is slidably movable within the cavity of the housing, the closure member having a second magnet. The closure member is configured to engage the seat to prevent fluid flow through the flow path in a reverse direction. The magnetic field generated by the first and second magnets biases the closure member into contact with the seat.

In another implementation, the invention is a closure member for a check valve. The closure member has a body extending from a first end to a second end along a longitudinal axis, the body having a cavity formed therein. The closure member further has an enlarged portion formed at the first end of the body, the enlarged portion having a sealing surface. A shaft portion extends from the enlarged portion to the second end. A plurality of protuberances extend from the shaft portion. A magnet is located within the cavity.

In a further implementation, the invention is a closure member for a check valve. The closure member has a body extending from a first end to a second end along a longitudinal axis. A first portion is formed at the first end of the body having a sealing surface. A plurality of protuberances extending from the first portion along the longitudinal axis, the plurality of protuberances defining a cavity. A magnet is located within the cavity.

Further areas of applicability of the present technology will become apparent from the detailed description provided hereinafter. It should be understood that the detailed description and specific examples, while indicating the preferred implementation, are intended for purposes of illustration only and are not intended to limit the scope of the technology.

### BRIEF DESCRIPTION OF THE DRAWINGS

The invention of the present disclosure will become more fully understood from the detailed description and the accompanying drawings, wherein:

FIG. 1 is a schematic of a system for manufacturing semiconductor devices utilizing one or more apparatuses for controlling flow.

FIG. 2 is a perspective view of a fluid delivery module comprising at least one apparatus for controlling flow as may be utilized in the process of FIG. 1.

FIG. 2A is a cross-sectional view of the fluid delivery module of FIG. 2 taken along line 2A-2A in FIG. 2.

FIG. 3 is a perspective view of a first component as may be utilized in the fluid delivery module of FIG. 2.

FIG. 4 is an exploded perspective view of the first component.

FIG. 5 is a cross-section view of the first component, taken along line 5-5 of FIG. 3.

FIG. 6 is a perspective view of a closure member of the first component.

FIG. 7 is an exploded perspective view of the closure member.

FIG. 8 is a front view of the closure member.

FIG. 9 is a rear view of the closure member.

FIG. 10 is a left side view of the closure member.

FIG. 11 is a cross-section view of the closure member taken along line 11-11 of FIG. 8.

FIG. 12 is a perspective view of a stop member of the first component.

FIG. 13 is an exploded perspective view of the stop member.

FIG. 14 is a front view of the stop member.

FIG. 15 is a rear view of the stop member.

FIG. 16 is a left side view of the stop member.

FIG. 17 is a cross-section view of the stop member taken along line 17-17 of FIG. 14.

FIG. 18 is a detail view of the area 18 of FIG. 5.

FIG. 19 is a perspective view of a second component as may be utilized in the fluid delivery module of FIG. 2.

FIG. 20 is an exploded perspective view of the second component.

FIG. 21 is a cross-section view of the second component, taken along line 21-21 of FIG. 19.

FIG. 22 is a perspective view of a third component as may be utilized in the fluid delivery module of FIG. 2.

FIG. 23 is an exploded perspective view of the third component.

FIG. 24 is a cross-section view of the third component, taken along line 24-24 of FIG. 22.

FIG. 25 is a perspective view of an upper housing member of the third component.

FIG. 26 is a lower rear perspective view of the upper housing member.

FIG. 27 is a top view of the upper housing member.

FIG. 28 is a bottom view of the upper housing member.

FIG. 29 is a cross-section view of the upper housing member taken along line 29-29 of FIG. 27.

FIG. 30 is a perspective view of a lower housing member of the third component.

FIG. 31 is a lower rear perspective view of the lower housing member.

FIG. 32 is a top view of the lower housing member.

FIG. 33 is a bottom view of the lower housing member.

FIG. 34 is a cross-section view of the lower housing member taken along line 34-34 of FIG. 32.

FIG. 35 is a perspective view of a fourth component as may be utilized in the fluid delivery module of FIG. 2.

FIG. 36 is an exploded perspective view of the fourth component.

FIG. 37 is a cross-section view of the fourth component, taken along line 37-37 of FIG. 35.

FIG. 38 is a perspective view of a closure member of the fourth component.

FIG. 39 is an exploded perspective view of the closure member.

FIG. 40 is a left side view of the closure member.

FIG. 41 is a cross-section view of the closure member taken along line 41-41 of FIG. 38.

FIG. 42 is an upper perspective view of another embodiment of a closure member as may be used in a component of the fluid delivery module.

FIG. 43 is a lower perspective view of the closure member.

FIG. 44 is a left side view of the closure member.

FIG. 45 is a cross-section view of the closure member taken along line 45-45 of FIG. 44.

FIG. 46 is an upper perspective view of another embodiment of a closure member as may be used in a component of the fluid delivery module.

FIG. 47 is a lower perspective view of the closure member.

FIG. 48 is a left side view of the closure member.

FIG. 49 is a cross-section view of the closure member taken along line 48-48 of FIG. 48.

All drawings are schematic and not necessarily to seale. Features shown numbered in certain figures which may appear un-numbered in other figures are the same features unless noted otherwise herein.

### DETAILED DESCRIPTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

The present invention is directed to a fluid flow component for use in a fluid delivery module comprising at least one apparatus for controlling fluid flow. In some embodiments, the fluid delivery module may include a mass flow controller to deliver a known mass flow of fluid to a semiconductor process or similar process. Semiconductor fabrication is one industry which demands high performance in control of fluid flows. As semiconductor fabrication techniques have advanced, customers have recognized the need for flow control devices with increased complexity and capability. Modern semiconductor processes require precise control over the delivered mass and volume flow rate as well as tight control over mixtures. The present invention provides for a fluid flow component having a check valve which can be utilized in a variety of applications within the fluid delivery module.

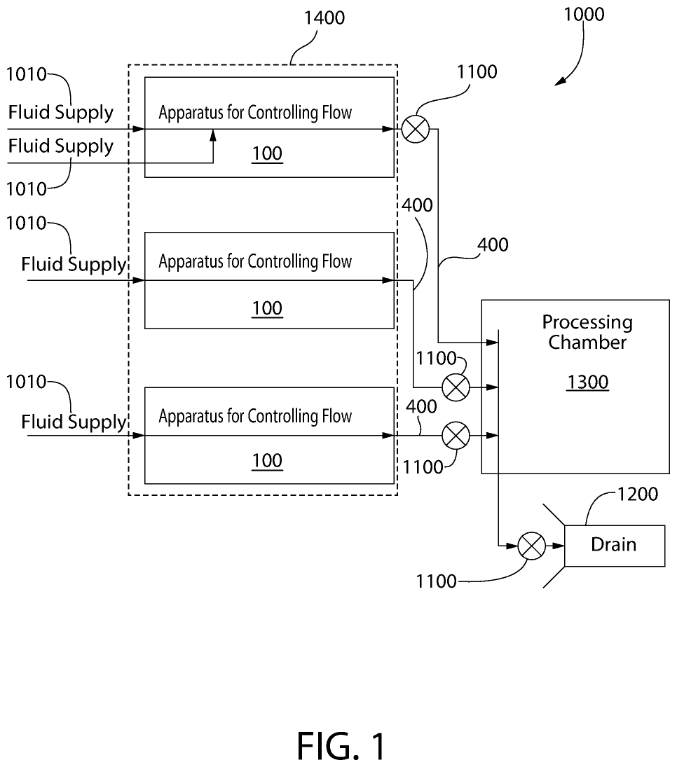

FIG. 1 shows a schematic of an exemplary processing system 1000. The processing system 1000 may utilize one or more apparatus for controlling flow 100 fluidly coupled to a processing chamber 1300. The apparatus for controlling flow 100 are used to supply one or more different process fluids to the processing chamber 1300. Fluids are provided by a plurality of fluid supplies, or fluid sources. Collectively, the plurality of apparatus for controlling flow 100 belong to a fluid delivery module 1400. Optionally, more than one fluid delivery module 1400 may be utilized in the processing system 1000. The plurality of apparatus for controlling flow 100 are connected to the processing chamber 1300 by an outlet manifold 400. Articles such as semiconductors and integrated circuits may be processed within the processing chamber 1300.

Valves 1100 isolate each of the apparatus for controlling flow 100 from the processing chamber 1300, enabling each of the apparatus for controlling flow 100 to be selectively connected or isolated from the processing chamber 1300, facilitating a wide variety of different processing steps. The processing chamber 1300 may contain an applicator to apply process fluids delivered by the plurality of apparatus for controlling flow 100, enabling selective or diffuse distribution of the fluids supplied by the plurality of apparatus for controlling flow 100. Optionally, the processing chamber 1300 may be a vacuum chamber or may be a tank or bath for immersing articles in the fluids supplied by the plurality of apparatus for controlling flow 100. A fluid supply line is formed by the flow path from each of the respective fluid supplies to the processing chamber 1300.

In addition, the processing system 1000 may further comprise a drain 1200 which is isolated from the processing chamber 1300 by a valve 1100 to enable evacuation of process fluids or facilitate purging one or more of the apparatus for controlling flow 100 to enable switching between process fluids in the same apparatus for controlling flow 100. Optionally, the drain 1200 may be a source of vacuum or may be a liquid drain configured to remove liquids from the processing chamber 1300. Optionally, the apparatus for controlling flow 100 may be mass flow controllers, flow splitters, or any other device which controls the flow of a process fluid in a processing system. Furthermore, the valves 1100 may be integrated into the apparatus for controlling flow 100 if so desired.

Processes that may be performed in the processing system 1000 may include wet cleaning, photolithography, ion implantation, dry etching, atomic layer etching, wet etching, plasma ashing, rapid thermal annealing, furnace annealing, thermal oxidation, chemical vapor deposition, atomic layer deposition, physical vapor deposition, molecular beam epitaxy, laser lift-off, electrochemical deposition, chemical-mechanical polishing, wafer testing, electroplating, or any other process utilizing fluids.

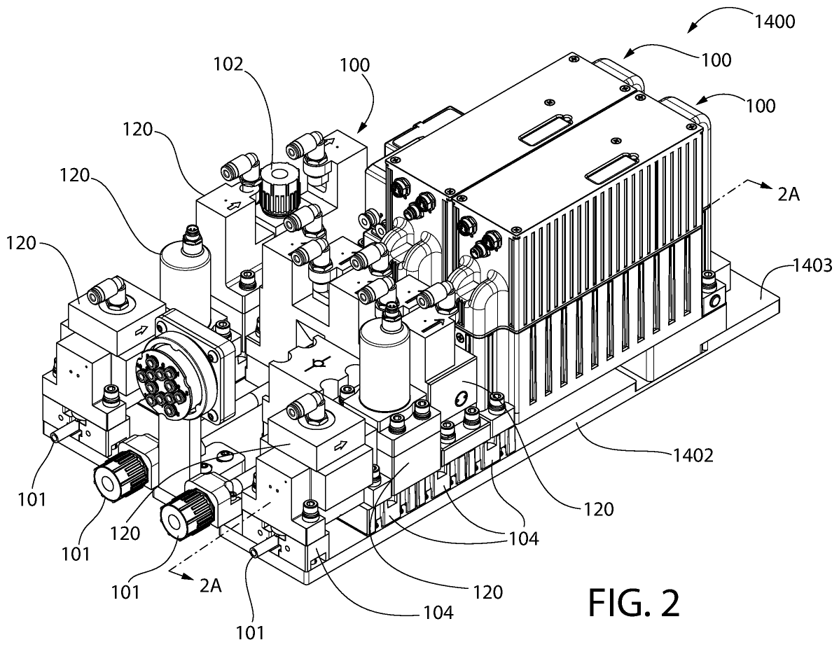

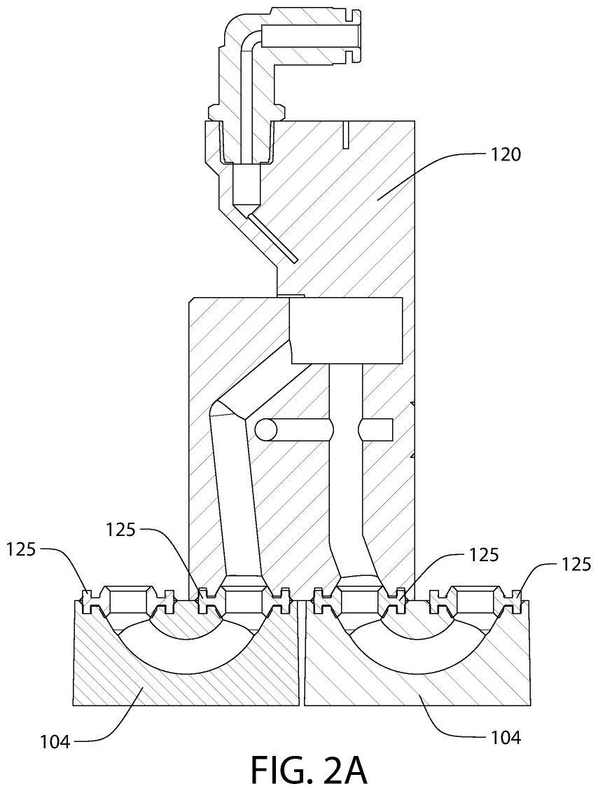

FIG. 2 shows a schematic of an exemplary fluid delivery module 1400. In this embodiment, the fluid delivery module 1400 has a plurality of apparatus for controlling flow 100 having a plurality of inlets 101 and a plurality of outlets 102. In some embodiments, the plurality of inlets 101 do not correspond to the plurality of outlets 102 in a one to one manner. Instead, a plurality of inlets 101 may be joined into a single outlet 102 and a single inlet 101 may be split into a plurality of outlets 102. This may be done to achieve mixing or combination of different fluids prior to providing them to the process chamber 1300. Nonetheless, at least one flow passage extends from one of the inlets 101 to one of the outlets 102, the flow passage being formed by the various components of the fluid delivery module 1400.

As can be seen, each of the apparatus for controlling flow 100 is arranged generally in a row, with the plurality of apparatus 100 in parallel rows. This need not be the case, and any packaging configuration may be used. The fluid delivery module 1400 has a substrate panel 1402. The substrate panel 1402 serves as support structure for the fluid delivery module 1400, but it may be simply used to facilitate assembly. The support structure 1402 may be referred to as a base substrate or base plate and is generally a flat plate or sheet with one or more apparatuses for controlling flow 100 mounted thereon. In the present example, a plurality of apparatus for controlling flow 100 are mounted to the support structure 1402. Each of the apparatus for controlling flow 100 are modular in design, and comprise a large number of individual fluid flow components 104, 120 which are each attached to the support structure 1402 either directly or indirectly. The support structure 1402 has an upper surface 1403 onto which the apparatuses for controlling flow 100 are mounted.

The components 104, 120 may include one or more substrate blocks 104 and one or more additional fluid flow components 120. The fluid flow components 120 and the substrate blocks 104 may be arranged such that the substrate blocks 104 are in direct surface contact with the upper surface 1403 of the substrate panel 1402. The fluid flow components 120 may be mounted to the substrate blocks 104 such that the fluid flow components 120 are indirectly mounted to the substrate panel 1402. In other implementations, the substrate blocks 104 may be indirectly mounted to the substrate panel 1402 and the additional fluid flow components 120 may be directly mounted to the substrate panel 1402.

The fluid flow components 104, 120 may comprise both active and passive fluid flow components. Passive flow components do not alter the flow of the fluid, but instead merely connect one active component to another or connect an active component to an inlet or outlet. Typically, substrate blocks 104 are passive fluid flow components. Active flow components may alter the flow of fluid, monitor an aspect of the fluid, or otherwise perform a function beyond mere fluid conveyance. Active flow components may include temperature sensors, pressure transducers, mass flow controllers, check valves, proportional valves, on/off valves, and the like. Yet other components may be both active and passive depending on their current use in an apparatus for controlling flow 100. For instance, a temperature sensor may also serve as a passive fluid flow component which conveys fluid from one active flow component to another and may or may not actually be utilized to measure temperature sensor. As can be seen, a huge number of variations in fluid flow components 104, 120 can be conceived, and these fluid flow components 104, 120 can be used to assemble a wide range of apparatus for controlling flow 100.

The fluid delivery module 1400 comprises a plurality of inlets 101 which receive fluid from the fluid supplies 1010 discussed above. The fluid delivery module 1400 also has at least one outlet 102 which delivers fluid to the processing chamber 1300. Each apparatus for controlling flow 100 may have one inlet 101 and one outlet 102 or may have a plurality of inlets 101 or a plurality of outlets 102. Thus, fluid may flow through a plurality of inlets 101 and be delivered via a single outlet 102 or may flow through a single inlet 101 and be delivered via a plurality of outlets 102. The same fluid may be delivered to a plurality of inlets 101 or different fluids may be delivered to each inlet 101. The same inlet 101 or outlet 102 may be shared by a plurality of apparatus for controlling flow 100 or each apparatus for controlling flow 100 may have one or more dedicated inlets 101 and outlets 102.

The substrate blocks 104 and the fluid flow components 120 comprise one or more fluid ports therein to conduct flow to or from one or more adjacent substrate blocks or fluid flow components 120 having corresponding fluid ports as discussed in greater detail below. The fluid flow components 120 may be one or more of a valve, a flow controller, a pressure transducer, a flow measurement sensor, a pressure regulator, a flow restrictor, an actuator, an inlet 101 or outlet 102, or any other known flow control component. A plurality of anchors are used to couple the fluid flow components 120 to the substrate blocks 104. The anchors may be threaded inserts or threads in the substrate blocks 104, threaded inserts or threads in the substrate panel 1402, nuts, or other anchoring features which permit secure fastening of the fluid flow components 120 and the substrate blocks 104.

FIG. 2A illustrates a partial cross-section of the fluid delivery module 1400. Specifically, a component 120 is illustrated mounted to first and second substrate blocks 104. The substrate blocks 104 and the component 120 have ports, each port having a seal cavity. Within the seal cavities of each of the substrate blocks 104 and the component 120 are seals 125 which seal the flow path extending through the first substrate block 104 to the component 120 and from the component 120 to the second substrate block 104. In order to accomplish this sealing, the ports of the substrate blocks 104 are aligned with ports of the component 120 and a seal 125 is installed within the corresponding seal cavities. When the component 120 is secured to the substrate blocks 104, a fluid-tight seal is achieved.

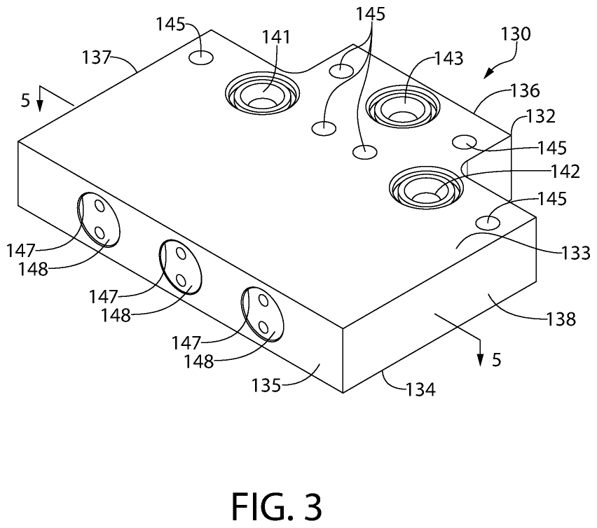

Turning to FIGS. 3-5, a fluid flow component 130 as may be used in the fluid delivery module 1400 is shown. In the present embodiment, the fluid flow component 130 is a fluid mixer intended to mix two or more fluids and output a fluid mixture. As shown, the fluid flow component 130 is a passive component, but in other configurations it may be configured as an active component capable of actively altering fluid flow. The component 130 has a housing 132, the housing 132 having a top surface 133, bottom surface 134, front surface 135, rear surface 136, left surface 137, and right surface 138. As can be seen, the rear surface 136 is not planar, but instead comprises a projection which extends from adjacent portions of the rear surface 136.

The top surface 133 of the housing 132 comprises a first port 141, a second port 142, and a third port 143. The first and second ports 141, 142 are configured to receive fluid while the third port 143 is configured to output fluid. However, in some embodiments, different ones of the first, second, and third ports 141, 142, 143 may serve as inlets and outlets. In addition, it is conceived that there may be more than three ports to facilitate combining more than two fluids or splitting one or more fluids. Each of the ports 141, 142, 143 comprises a seal cavity 144 which is configured to receive a seal to facilitate connection with other components. The housing 132 further comprises a plurality of fastener passageways 145 that facilitate attachment of the housing 132 to the support structure 1402. In addition, the fastener passageways 145 can facilitate attachment of other flow components 104, 120 to the housing 132. The fastener passageways 145 may be through holes, threaded holes, or may be formed in any manner that permits attachment.

The bottom surface 134 of the housing 132 is configured to be in physical contact with the upper surface 1403 of the support structure 1402 when the fluid flow component 130 is mounted to the support structure 1402. However, in other embodiments, the upper surface 1403 may face the top surface 133 if the fluid flow component 130 is attached to another fluid flow component 104, 120, the other fluid flow component 104, 120 being directly coupled to the support structure 1402.

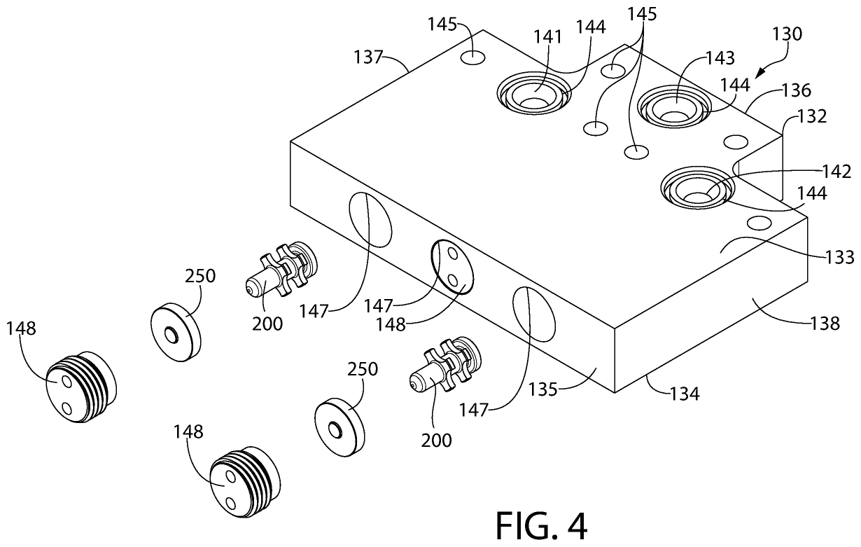

The front surface 135 and the left surface 137 collectively comprise a plurality of assembly ports 147. Each of the assembly ports 147 comprises a retention component 148 which provides a fluid-tight seal for the assembly ports 147 and retains any components installed in the assembly ports 147. For example, FIG. 4 illustrates an exploded view of the retention component 148 removed from the housing 132. A closure member 200 and a stop member 250 are also shown. The stop member 250 is retained by the retention component 148 and also seals the assembly port 147 to prevent leakage of fluid through the assembly port 147.

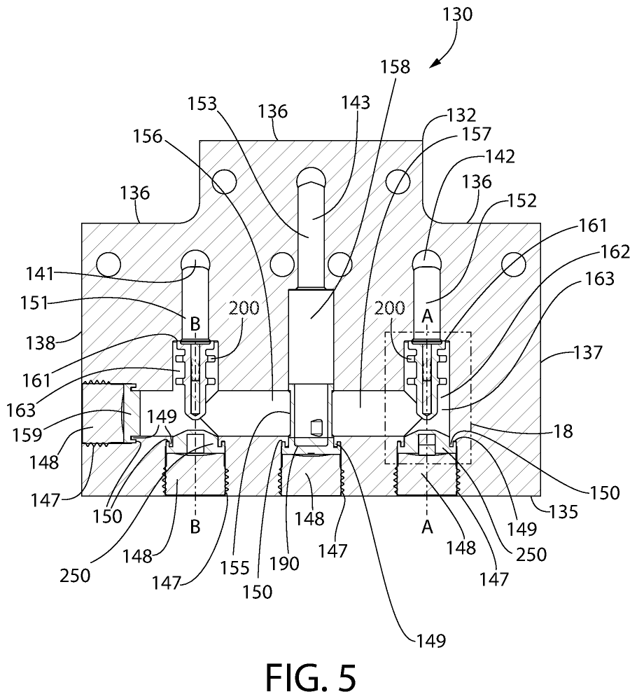

FIG. 5 illustrates a cross-section of the fluid flow component 130 in the assembled condition. The fluid flow component 130 has first, second, and third flow paths 151, 152, 153 extending from the first, second, and third ports 141, 142, 143 to a junction 155. A mixing element 190 is located at a junction 155. Thus, fluid can flow from the first port 141 through the first flow path 151 to the junction 155. Fluid can also flow from the second port 142 through the second flow path 152 to the junction 155. Fluid can flow from the junction 155 through the third flow path 153 to the third port 143. The first, second, and third flow paths 151, 152, 153 meet to form a T shape at the junction 155. The first, second, and third flow paths 151, 152, 153 collectively form a flow path extending from inlets at the first and second ports 141, 142 to an outlet at the third port 143.

More specifically, the first flow path 151 has a first conduit 156, the first conduit 156 being immediately adjacent the junction 155. The second flow path 152 has a second conduit 157, the second conduit 157 being immediately adjacent the junction 155. The third flow path 153 has a third conduit 158, the third conduit 158 being immediately adjacent the junction 155. The first and second conduits 156, 157 of the first and second flow paths 151, 152 are co-linear while the third conduit 158 of the third flow path 153 is perpendicular to the first and second conduits 156, 157 of the first and second flow paths 151, 152. Thus, fluid flows along the first and second flow paths 151, 152 and meets at the junction 155. Fluid then proceeds from the junction 155 via the third conduit 158 of the third flow path 153 at a right angle from both of the first and second conduits 156, 157 of the first and second flow paths 151, 152.

Check valves are located in the first and second flow paths 151, 152 to prevent back-flow of the fluids supplied to the first and second ports 141, 142. Check valves are formed by a seat 161 formed in the housing 132, a closure member 200, and, optionally, a stop member 250. The seat 161 may be an integrally formed, monolithic, portion of the housing 132 or may be a separate component which is installed into or coupled to the housing 132. The seat 161 may have a flat surface or may incorporate separate sealing members or features to promote effective sealing with the closure member 200. Thus, the check valves prevent back-flow from the third port 143 to exit either of the first or second ports 141, 142 as a result of the sealing of the closure member 200 against the seat 161.

The closure member 200 is located within a cavity 162 in the housing 132 which is accessible via an adjacent assembly port 147. The closure member 200 is slidably movable within the cavity 162 along a longitudinal axis A-A, B-B and is configured to prevent fluid flow when the closure member 200 is in contact with the seat 161. Preferably, the closure member 200 moves either concentric with or parallel to its respective longitudinal axis A-A, B-B. The longitudinal axes A-A, B-B extend along their respective cavities 162. The seats 161 are preferably concentric about their respective longitudinal axes A-A, B-B and the cavities 162 are concentric about their respective longitudinal axes A-A, B-B. The cavities 162 each have a cylindrical inner surface 163 which is concentric about their respective longitudinal axis A-A, B-B. Similarly, the stop members 250 are aligned with and symmetric about their respective longitudinal axes A-A, B-B.

Each of the closure members 200 is installed via an assembly port 147 and retained by a retention component 148. The retention components 148 may be threaded and the assembly port 147 may have corresponding threads to allow securing the stop member 250 within the assembly port 147. The stop member 250 may form a seal. Alternately, in other assembly ports 147 a seal 159 may be used to seal the assembly port 147. Similarly, the mixing element 190 may also incorporate features which provide a sealing function to seal the assembly port 147. Alternatively, other known retention means may be utilized as desired. In yet other configurations, the stop member 250 may be substituted for a seal 159.

The assembly port 147 located on the left side 137 of the housing 132 does not have a component inserted therein, but instead includes a seal 159 to prevent leakage. The seal 159 has a primary purpose to seal the assembly port 147. However, it is possible to utilize one or more assembly ports 147 to enable additional fluid connections and omit the seal As can be seen, each of the mixing element 190, stop members 250, and seal 159 engage an annular rib 149 within the assembly ports 147. This annular rib 149 ensures that sealing is achieved and provides an axial constraint for the mixing element 190, stop members 250, and seal 159. Thus, the annular rib 149 and a corresponding annular groove 150 ensure that the components are properly retained within the assembly port 147 and seal to prevent fluid leakage.

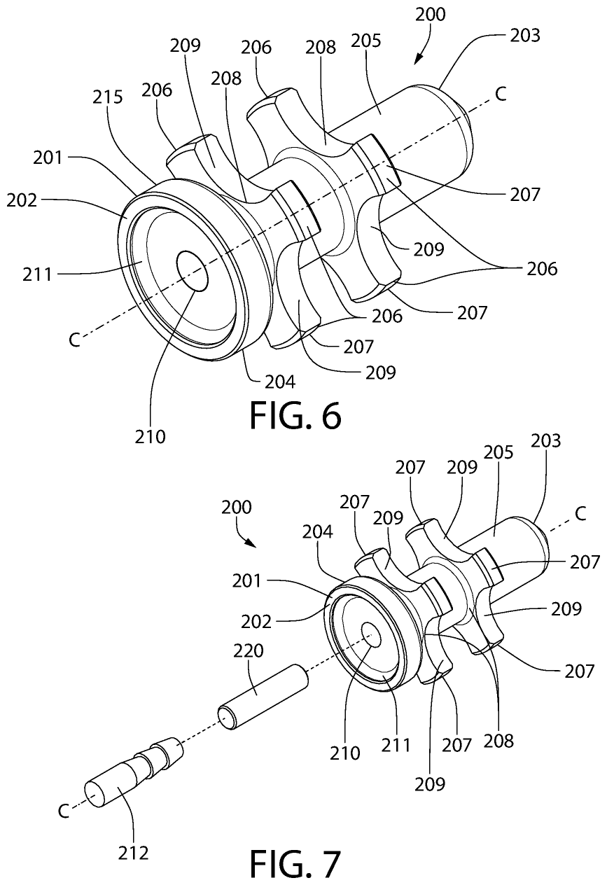

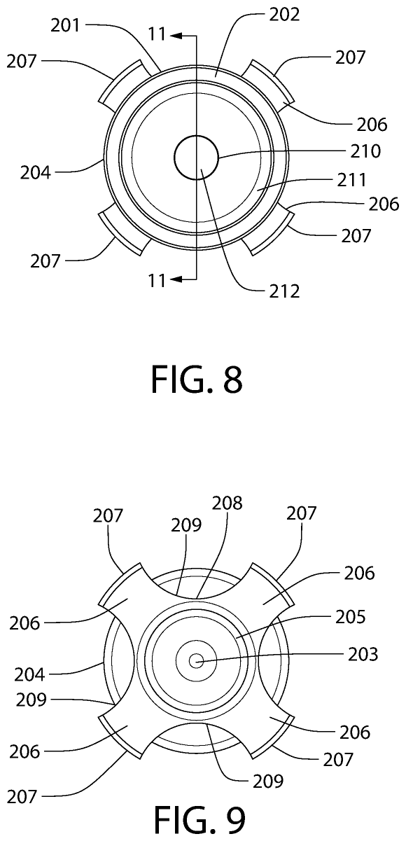

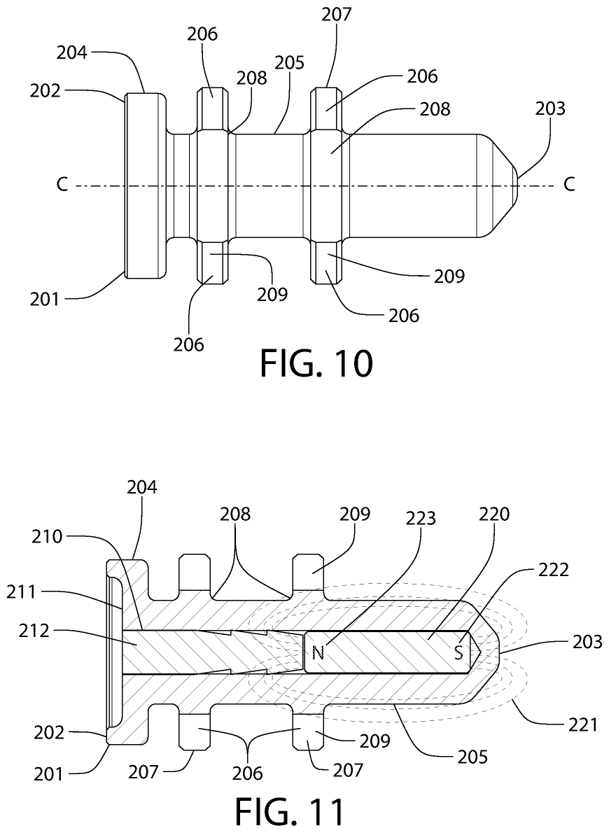

FIGS. 6-11 illustrate the closure member 200 in greater detail. The closure member 200 has a body 215 that extends from a first end 201 to a second end 203 along a longitudinal axis C-C. The closure member 200 has a sealing surface 202 at the first end 201, formed on an enlarged portion 204 of the closure member 200. A shaft portion 205 extends from the enlarged portion 204 to the second end 203. A plurality of protuberances 206 extend from the shaft portion 205. The plurality of protuberances 206 have an arcuate outer portion 207 such that the plurality of protuberances 206 form portions of first and second annular rings 208. The arcuate outer portions 207 preferably have the same radius and are centered about the longitudinal axis C-C. This allows the arcuate outer portions 207 to engage the inner surface 163 of the cavity 162.

The annular rings 208 have gaps 209 between adjacent ones of the plurality of protuberances 206. This allows fluid to flow past the annular rings 208 while the arcuate outer portions 207 of the plurality of protuberances 206 engage the inner surface 163 of the cavity 162. Thus, the arcuate outer portions 207 of the plurality of protuberances 206 maintain the closure member 200 within the cavity 162. The arcuate outer portions 207 of the plurality of protuberances 206 are sized so that the closure member 200 is prevented from moving laterally or radially with respect to the longitudinal axis A-A, B-B. Otherwise stated, the closure member 200 is free to move along the respective longitudinal axis A-A, B-B while being prevented from moving radially. The longitudinal axis A-A, B-B is substantially co-axial with the longitudinal axis C-C when the closure member 200 is within the cavity 162. Preferably, the enlarged portion 204 has a diameter which is less than or equal to a diameter of the arcuate outer portions 207 of the plurality of protuberances 206.

The closure member 200 further comprises a cavity 210 formed within a recess 211 at the first end 201. The recess 211 is within the enlarged portion 204 while the cavity 210 extends through the enlarged portion 204 and into the shaft portion 205. The recess 211 and the cavity 210 are symmetric about the longitudinal axis C-C. A magnet 220 is located within the cavity 210 and a sealing element 212 is installed into the cavity 210 to seal the magnet 220 within the cavity 210.

The magnet 220 has a magnetic field 221 which extends from a south pole 222 to a north pole 223. Thus, the magnet 220 generates the magnetic field 221. The south pole 222 is adjacent the second end 203 while the north pole 223 is adjacent the first end 201. Optionally, the orientation of the magnet 220 may be reversed as desired. Furthermore, more than one magnet 220 may be utilized or other magnetic materials may be used. The magnetic field 221 forms a portion of the total magnetic field of the fluid flow component 130, but additional magnetic fields from other sources may form a portion of the total magnetic field of the fluid flow component.

In other implementations, a magnetic material may be utilized for the magnet 220 or other materials may be substituted. For example, iron, nickel, cobalt, or a rare-earth metal may be used. Alternately, copper, gold, calcium, aluminum, or similar materials or alloys may be utilized for their properties as diamagnetic or paramagnetic materials. In yet other implementations, an electromagnet may be utilized in place of the magnet 220.

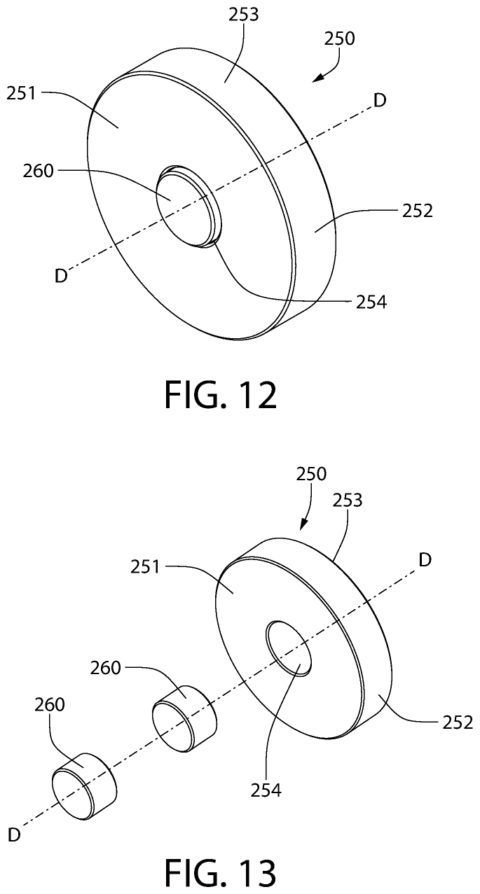

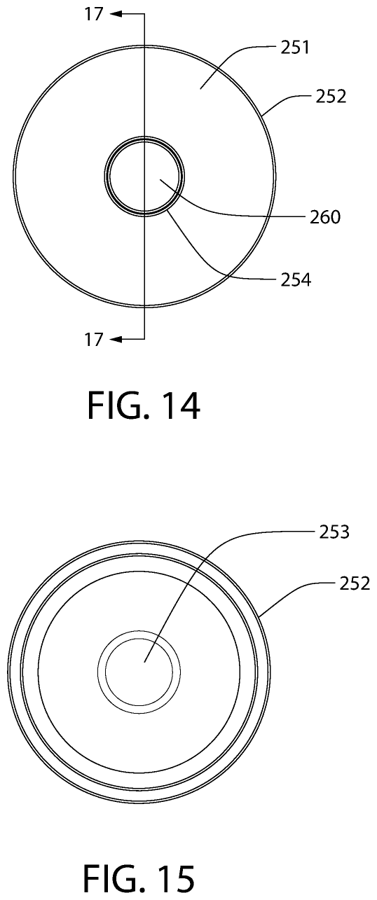

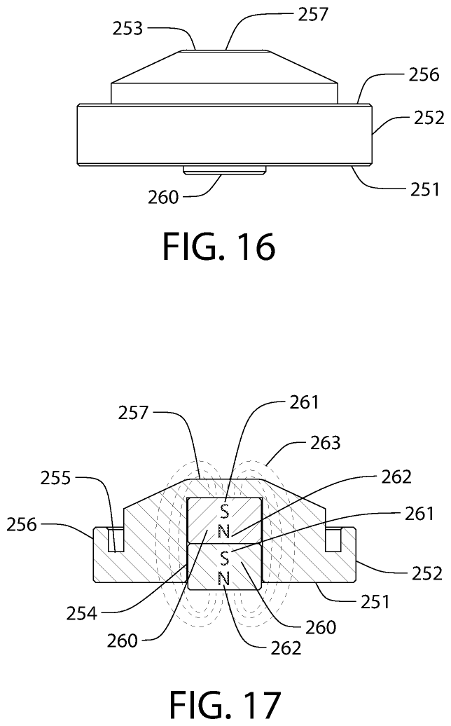

Turning to FIGS. 12-17, the stop member 250 is illustrated. The stop member 250 extends from a first side 251 to a second side 253 along a longitudinal axis D-D. An outer surface 252 is cylindrical and extends from the first side 251 to the second side 253. The first side 251 has a pocket 254 which receives two magnets 260. Optionally, the two magnets 260 may be identical. In other implementations, greater or fewer magnets 260 may be utilized. In yet other configurations, the magnets 260 may be substituted for one larger magnet, or larger or smaller magnets may be utilized. The pocket 254 receives the magnets 260 but does not extend through to the second side 253. As will be apparent, the magnetic forces increase non-linearly with decreasing distance between the magnets 220, 260. In addition, the magnetic forces are not constant or substantially constant. Thus, when the closure member 200 is in contact with the stop member 250, the magnetic force is far higher than when the closure member 200 is in contact with the seat 161.

The second side 253 incorporates an annular groove 255 and an annular rib 256 which engage the corresponding annular rib 149 and annular groove 150 of the assembly ports 147 of the housing 132. The annular groove 255 and annular rib 256 seal the assembly ports 147 to prevent leakage of fluid within the housing 132. In addition, the second side 253 incorporates a stop surface 257. When the closure member 200 is within the cavity, the stop surface 257 serves as a travel limit for the closure member 200. The stop surface 257 may engage the second end 203 when the closure member 200 is moved against the stop member 250. Thus, the closure member is constrained along the longitudinal axis by the seat 161 and the stop surface 257.

The magnets 260 generate a magnetic field 263, with field lines illustrated extending from a north pole to an opposite south pole. In the present embodiment, the magnets 260 have a south pole 261 proximate the second side 253 and a north pole 262 proximate the first side 251. However, this arrangement could be reversed as desired. The magnetic field 263 extends from one pole and loops around the magnets 260 to return to the opposite pole as illustrated. As with the magnetic field 221, the magnetic field 263 forms a portion of the total magnetic field of the fluid flow component 130. As with the magnet 220, the magnets 260 may be substituted for any magnetic, ferromagnetic, diamagnetic, or paramagnetic materials or alloys.

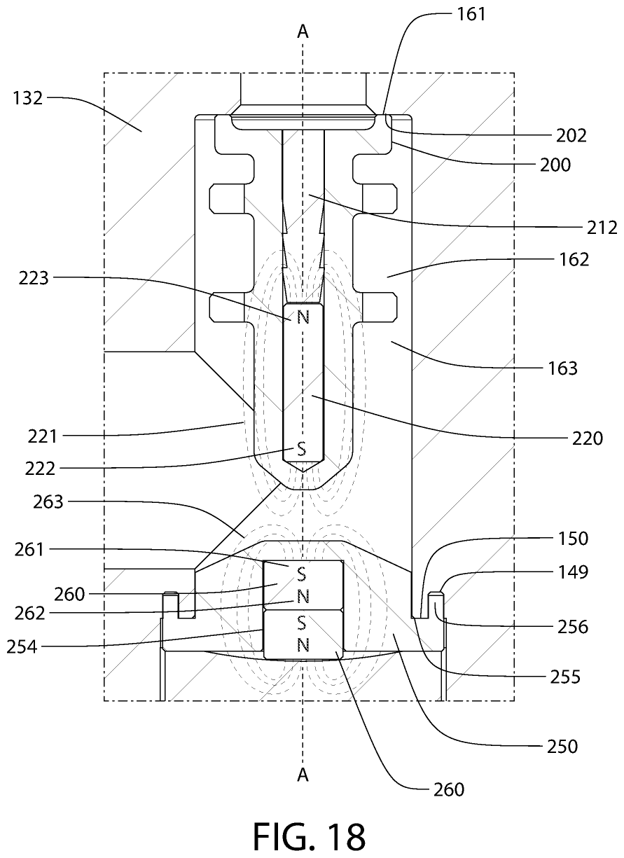

FIG. 18 is a detail view of FIG. 5 showing one of the check valve assemblies in greater detail. As illustrated, the sealing surface 202 of the closure member 200 is in contact with the seat 161 of the housing 132. The closure member 200 is biased against the seat 161 of the housing 132 as a result of the magnetic fields 221, 263 generated by the magnets 220, 260. The resulting combined magnetic field has field lines arranged such that the field lines of the magnetic field 221 of the magnet 220 are spaced and isolated from the field lines of the magnetic field 263 of the magnets 260. This is as a result of the south poles 222, 261 of the magnets 220, 260 being arranged proximate one another.

In other words, the combined magnetic field results in field lines of the magnetic field 221 which do not intersect the field lines of the magnetic field 263. This is caused by having the magnets 220, 260 in opposite orientations such that the two south poles 222, 261 face each other. This results in a repelling force between the magnets 220, 260 which causes the closure member 200 to be pressed against the seat 161 of the housing 132. The same effect could be achieved by positioning opposing north poles of the magnets 220, 260 in proximity, reversing both of the magnets 220, 260. In yet other configurations, the magnets 220, 260 may be substituted for another material or an electromagnet to generate the required repelling force. In yet further configurations, the magnets 220, 260 may be arranged differently to apply a force between the closure member 200 and the seat 161.

The seat 161 of the housing 132 seals against the sealing surface 202 of the closure member 200 when the closure member 200 is in contact with the seat 161. The seat 161 engages the sealing surface 202, preventing fluid flow from the third port 143 to the first or second ports 141, 142. The closure member 200 is moved from the seat 161 when fluid is flowed through the first or second ports 141, 142. The fluid flow moves the closure member 200 away from the seat 161 along the respective longitudinal axis A-A, B-B, allowing fluid to flow past the closure member 200 and out of the third port 143. The sealing contact pressure between the seat 161 and the sealing surface 202 can be altered by changing the relative distance between the magnets 220, 260. In addition, magnets having greater or smaller magnetic field strength will also change the sealing contact pressure between the seat 161 and the sealing surface 202.

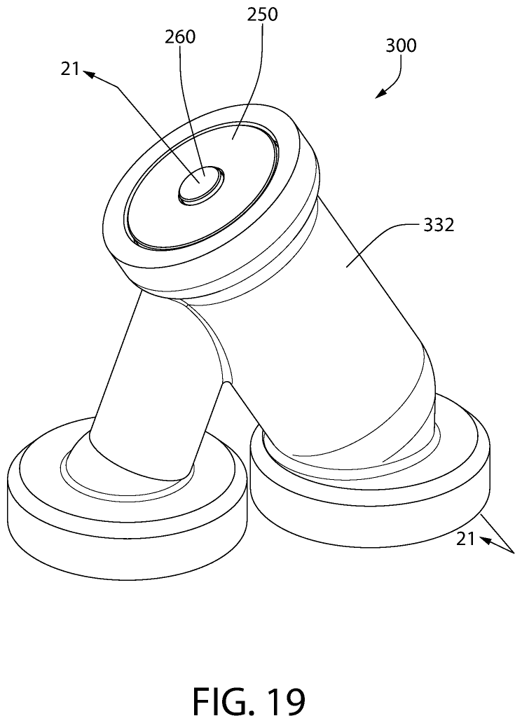

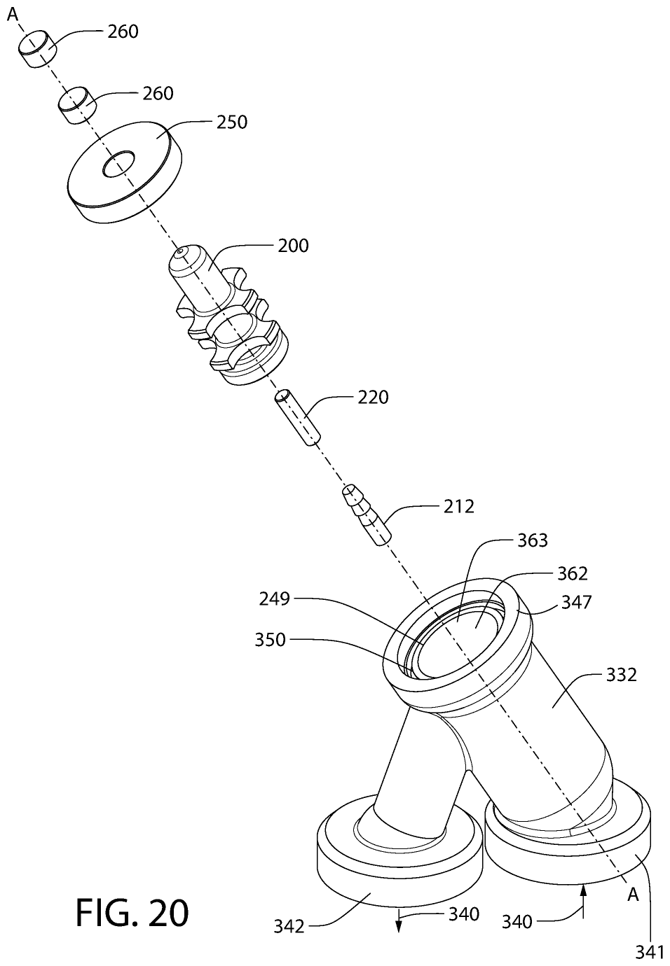

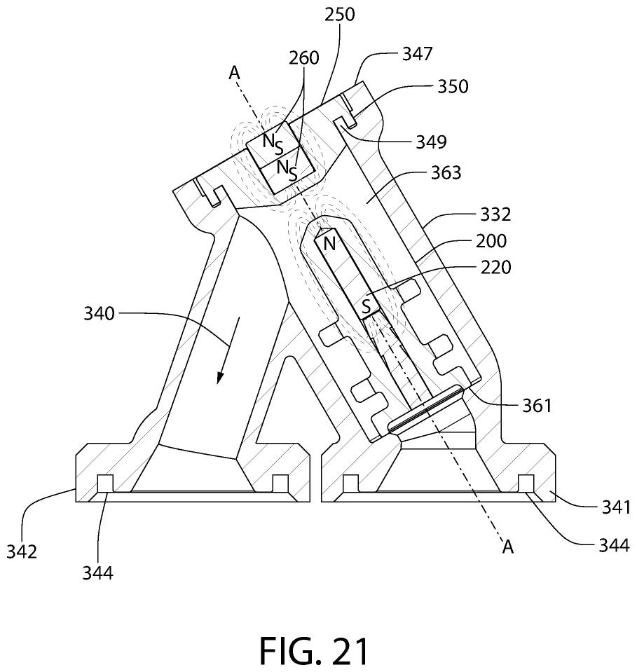

Turning to FIGS. 19-21, a second fluid flow component 300 is illustrated. The second fluid flow component 300 may be utilized in the fluid delivery module 1400 as a standalone check valve component or may be integrated into another component as is done with the fluid flow component 130, which incorporates two check valve assemblies and a mixing element. The fluid flow component 300 may also incorporate additional housing members which facilitate mounting of the second fluid flow component 300 to substrate blocks 104 or other components 120. The second fluid flow component has a housing 332, a stop member 250, and a closure member 200. The stop member 250 and closure member 200 are identical to those described above, although the stop member 250 and the closure member 200 need not be identical and may have variations in some dimensions or other features if necessary for a specific fluid flow component.

The housing 332 has a first port 341 at an inlet and a second port 342 at an outlet. A fluid flow path 340 extends from the first port 341 to the second port 342. Each of the first and second ports 341, 342 have a seal cavity 344. An assembly port 347 is in fluid communication with the flow path 340. The assembly port 347 has an annular rib 349 and an annular groove 350. The housing 332 further comprises a cavity 362 which extends along a longitudinal axis A-A. The cavity 362 is substantially cylindrical and is symmetrical about the longitudinal axis A-A. The cavity 362 has an inner surface 363 which engages the closure member 200 to allow the closure member 200 to move along the longitudinal axis A-A.

The cavity 362 terminates in a seat 361. The seat 361 engages the sealing surface 202, preventing fluid flow from the second port 342 to the first port 341. The closure member 200 is moved from the seat 361 when fluid is flowed through the first port 341. The fluid flow moves the closure member 200 away from the seat 361 along the longitudinal axis A-A, allowing fluid to flow past the closure member 200 and out of the second port 342. The sealing contact pressure between the seat 361 and the sealing surface 202 can be altered by changing the relative distance between the magnets 220, 260. In addition, magnets having greater or smaller magnetic field strength will also change the sealing contact pressure between the seat 361 and the sealing surface 202.

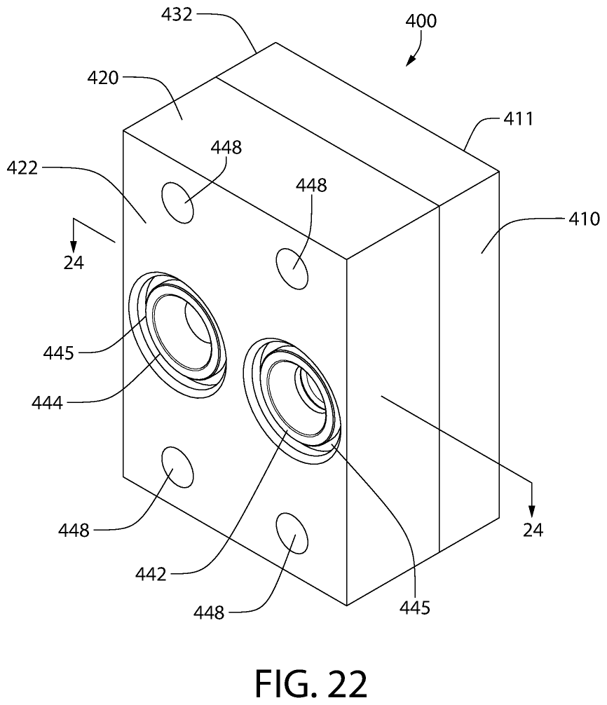

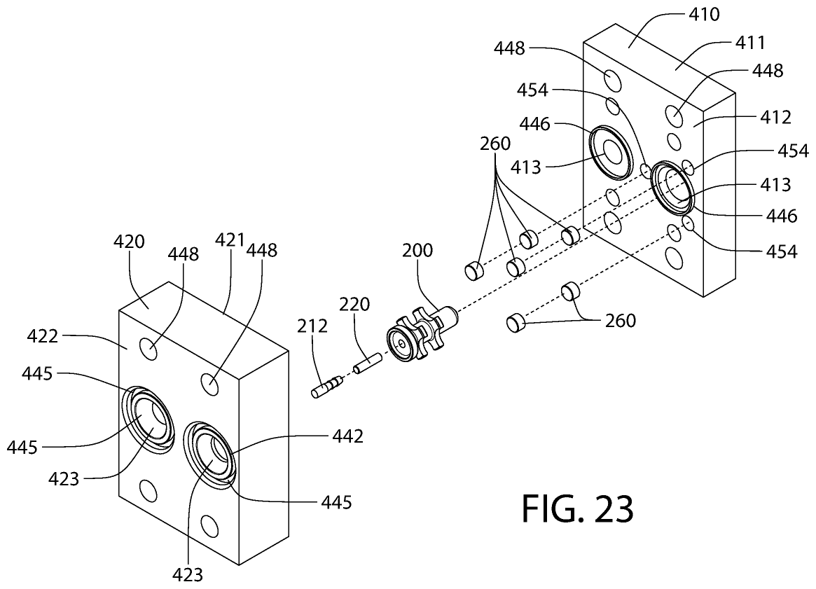

FIGS. 22-24 illustrate a third fluid flow component 400. The third fluid flow component 400 is a check valve having ports on opposite sides of the fluid flow component 400, allowing flexible configuration of the fluid delivery module 1400. The third fluid flow component 400 has a housing 432, the housing 432 formed of an upper housing member 410 and a lower housing member 420. The upper housing member 410 has an upper surface 411 and the lower housing member 420 has a lower surface 422. The upper surface 411 and the lower surface 422 form the upper and lower surfaces of the housing 432. The third fluid flow component 400 also has a closure member 200, but does not utilize a separate stop member 250. The features of the stop member 250 are incorporated into the housing 432 as will be discussed in greater detail below.

The upper surface 411 of the upper housing member 410 has a first port 441 and a third port 443. The lower surface 422 of the lower housing member 420 has a second port 442 and a fourth port 444. A first fluid flow path 440 extends from the second port 442 to the first port 441, the second port 442 serving as an inlet and the first port 441 serving as an outlet for the first fluid flow path 440. Similarly, a second fluid flow path 439 extends from the fourth port 444 to the third port 443. The second fluid flow path 439 is isolated from the first fluid flow path 440. Each of the first, second, third, and fourth ports 441, 442, 443, 444 have seal cavities 445.

The upper housing member 410 also has a lower surface 412 and the lower housing member 420 has an upper surface 421. The lower surface 412 engages the upper surface 421 to provide the complete housing 432. The lower surface 412 comprises an annular ring 446 surrounding each of the passages 413 in the upper housing member 410 that form the flow paths 440, 439. Similarly, the upper surface 421 comprises an annular groove 447 surrounding each of the passages 423 in the lower housing member 420 that form the flow paths 440, 439. The annular groove 447 receives the annular ring 446 to provide a seal between the upper housing member 410 and the lower housing member 420 and prevent leakage of fluid from the passages 413, 423. A plurality of fastener holes 448 extend through the upper and lower housing members 410, 420.

The upper housing member 420 further incorporates a cavity 462 and a seat 461. The cavity 462 extends from the upper surface 421 to the seat 461. The cavity 462 forms a portion of the first fluid flow path 439. The cavity 462 has an inner surface 463 that is cylindrical and substantially constant in diameter. The cavity 462 extends along a longitudinal axis A-A and is symmetric about the longitudinal axis A-A. As before, the seat 461 may be a flat surface or may have an insert, sealing features, or other variations in shape to facilitate sealing between the seat 461 and the closure member 200.

The closure member 200 is radially constrained within the cavity 462 by the inner surface 463, but is free to move along the longitudinal axis A-A. The travel of the closure member 200 is limited by the seat 461 in one direction and by an inner surface 414 of the passage 413 of the upper housing member 410 in the opposite direction with respect to the longitudinal axis A-A. As illustrated, the inner surface 414 of the passage 413 has a conical portion and a cylindrical portion. Thus, the closure member 200 will contact the inner surface 414 and is only capable of moving a limited distance from the seat 461. It is contemplated that the geometry of the passage 413 may be altered in any desired manner to achieve the required travel limitations while simultaneously allowing fluid flow past the closure member 200.

The upper housing member 410 further comprises a plurality of pockets 454 which receive magnets 260. There are three pockets 454 located at an equal distance from the longitudinal axis A-A, the pockets 454 configured to receive two magnets 260. The pockets 454 have a depth which is approximately equal to a height of three of the magnets 260, but may have a greater or lesser depth as desired. A greater or fewer number of magnets 260 may be utilized, and the magnets 260 may be larger or smaller than those illustrated. Preferably, the pockets 454 are equally spaced about the longitudinal axis A-A to ensure a consistent magnetic field and a symmetric application of magnetic forces on the closure member 200. Optionally, greater or fewer than three pockets 454 could be utilized as desired.

The magnets 260 generate a magnetic field 263, with field lines illustrated extending from a north pole 262 to an opposite south pole 261. In the present embodiment, the magnets 260 have a south pole 261 proximate the upper surface 411 and a north pole 262 proximate the lower surface 412. However, this arrangement could be reversed as desired. The magnetic field 263 extends from one pole and loops around the magnets 260 to return to the opposite pole as illustrated. As with the magnetic field 221, the magnetic field 263 forms a portion of the total magnetic field of the fluid flow component 130. As with the magnet 220, the magnets 260 may be substituted for any magnetic, ferromagnetic, diamagnetic, or paramagnetic materials or alloys.

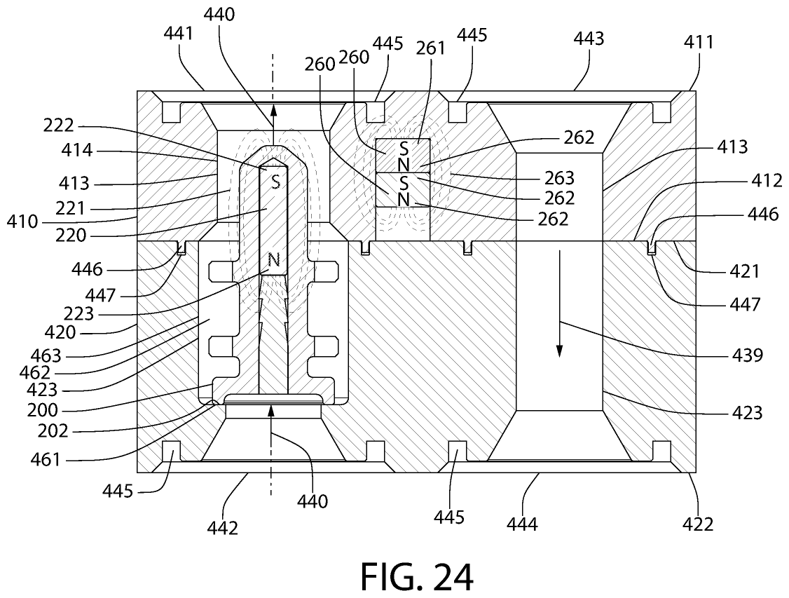

As best illustrated in FIG. 24, the sealing surface 202 of the closure member 200 is in contact with the seat 461 of the lower housing member 420 of the housing 432. The closure member 200 is biased against the seat 461 of the housing 432 as a result of the magnetic fields 221, 263 generated by the magnets 220, 260. The resulting combined magnetic field has field lines arranged such that the field lines of the magnetic field 221 of the magnet 220 are spaced and isolated from the field lines of the magnetic field 263 of the magnets 260. This is as a result of the south poles 222, 261 of the magnets 220, 260 being arranged proximate one another. The magnets 220, 260 are arranged substantially parallel to one another while being offset with respect to the longitudinal axis.

In other words, the combined magnetic field results in field lines of the magnetic field 221 which do not intersect the field lines of the magnetic field 263. This is caused by having the magnets 220, 260 in the same orientation and offset with respect to the longitudinal axis such that the two south poles 222, 261 are adjacent and the two north poles 223, 262 are adjacent. This results in a repelling force between the magnets 220, 260 which causes the closure member 200 to be pressed against the seat 461 of the housing 432. The same effect could be achieved by positioning opposing north poles of the magnets 220, 260 parallel and offset from one another in the opposite orientation, reversing both of the magnets 220, 260. In yet other configurations, the magnets 220, 260 may be substituted for another material or an electromagnet to generate the required repelling force. In yet further configurations, the magnets 220, 260 may be arranged differently to apply a force between the closure member 200 and the seat 461. The present arrangement results in a magnetic force which is nearly constant with respect to distance along the longitudinal axis, allowing more consistent force applied to the closure member 200.

The seat 461 of the housing 432 seals against the sealing surface 202 of the closure member 200 when the closure member 200 is in contact with the seat 461. The seat 461 engages the sealing surface 202, preventing fluid flow from the first port 441 to the second ports 442. The closure member 200 is moved from the seat 461 when fluid is flowed through the second port 442. The fluid flow moves the closure member 200 away from the seat 461 along the respective longitudinal axis A-A, allowing fluid to flow past the closure member 200 and out of the first port 441. The sealing contact pressure between the seat 461 and the sealing surface 202 can be altered by changing the relative distance between the magnets 220, 260. In addition, magnets having greater or smaller magnetic field strength will also change the sealing contact pressure between the seat 461 and the sealing surface 202.

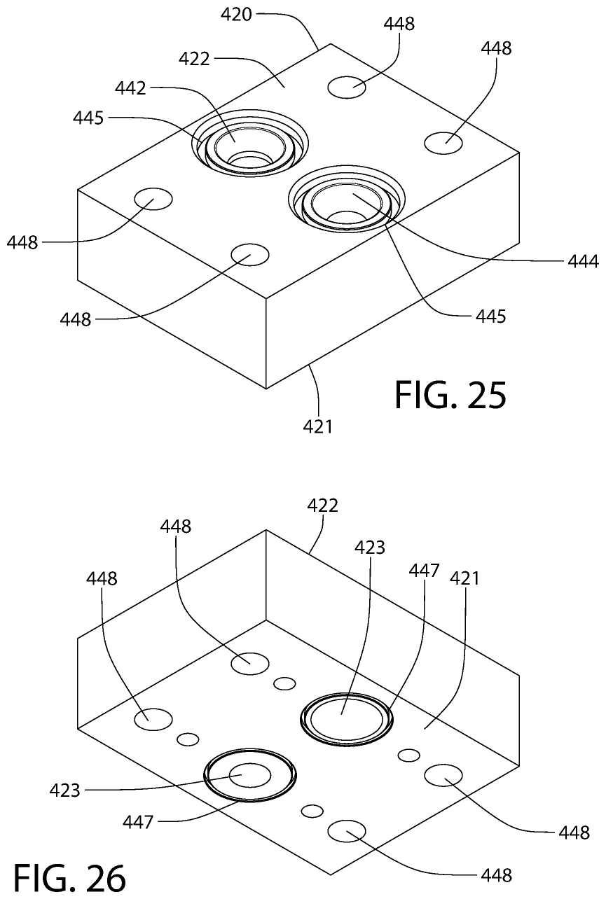

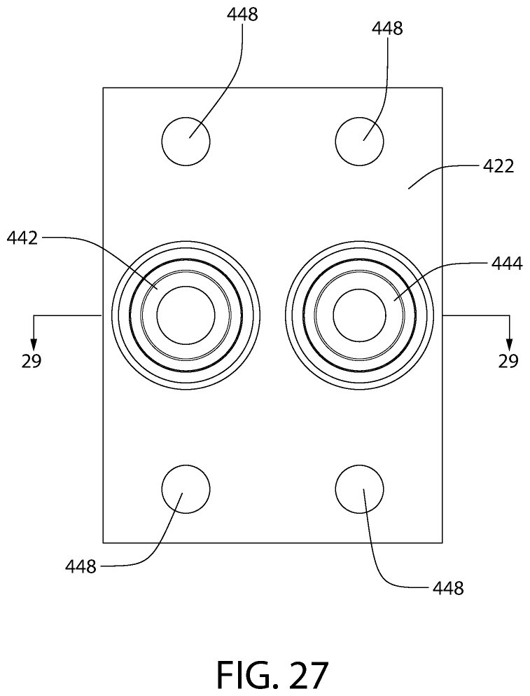

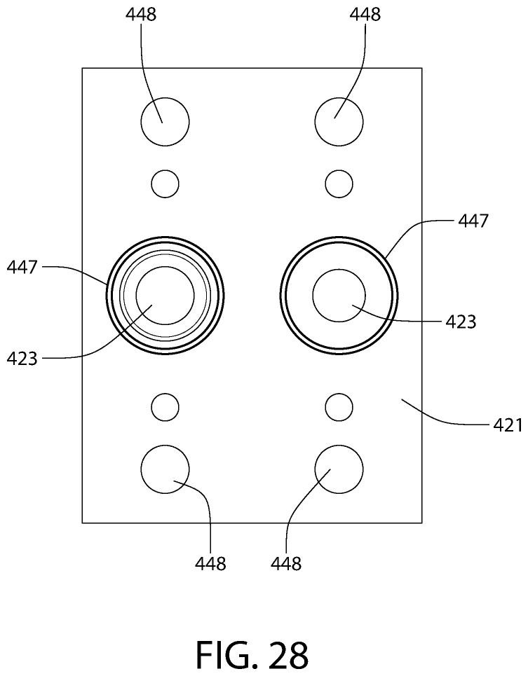

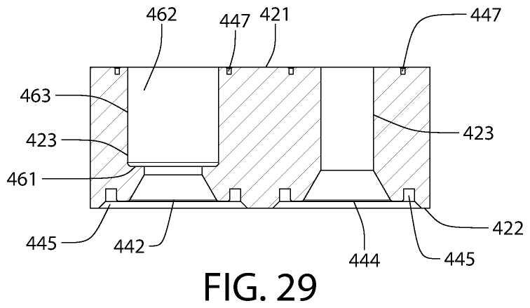

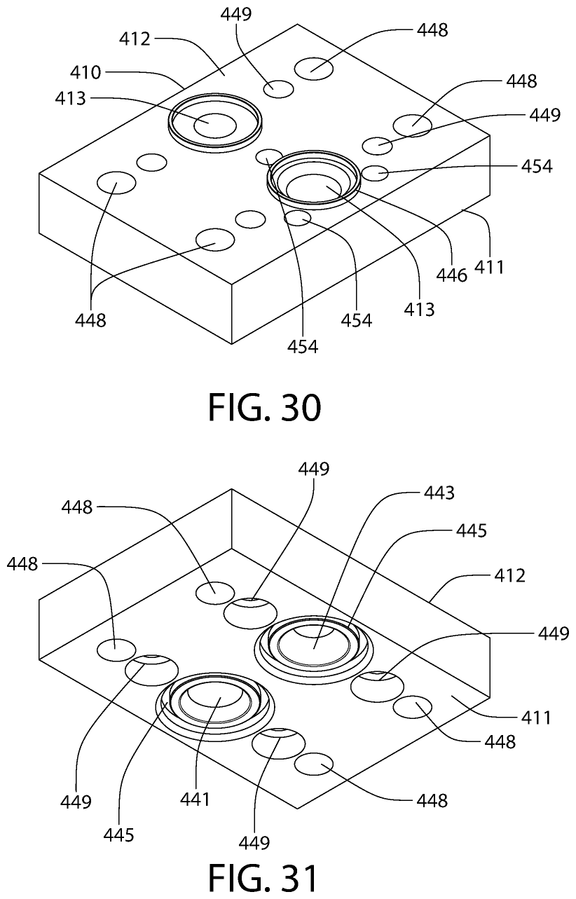

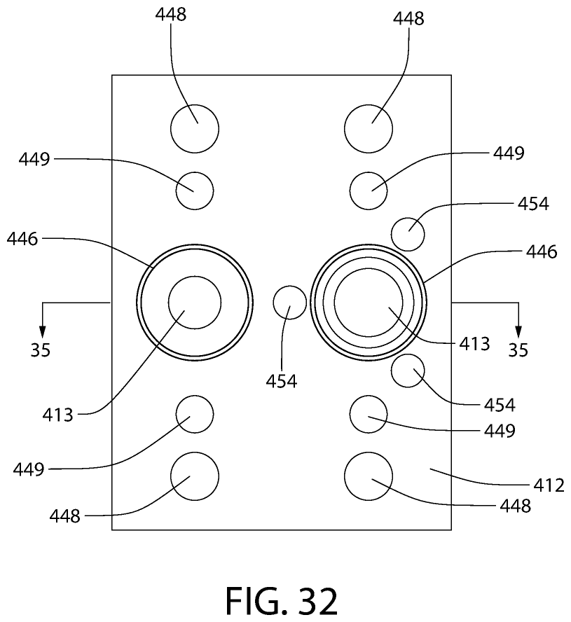

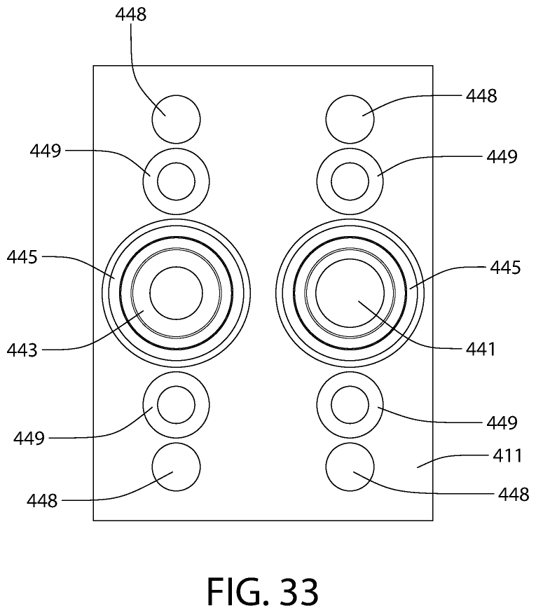

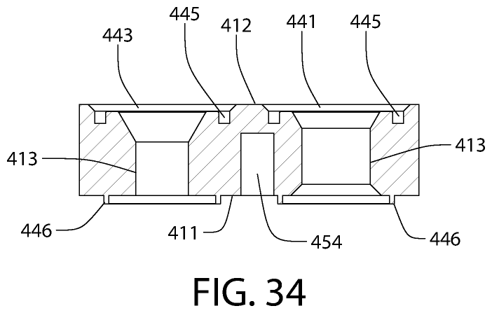

FIGS. 25-34 illustrate the upper and lower housing members 410, 420 in greater detail. The lower housing member 420 is illustrated in FIGS. 25-29 while the upper housing member 410 is illustrated in FIGS. 30-34. The lower housing member 420 has an upper surface 421 and a lower surface 422. The lower surface 422 has a second port 442 and a fourth port 444, each of the second and fourth ports 442, 444 having a seal cavity 445. Passages 423 extend from the second and fourth ports 442, 444 in the lower surface 422 to the upper surface 421. A cavity 462 is formed into the passage 423 that is fluidly coupled to the second port 442, the cavity terminating in the seat 461. The cavity has an inner surface 463 which is cylindrical. Grooves 447 are formed into the upper surface 421. Fastener passageways 448 extend through the lower housing member 420 from the upper surface 421 to the lower surface 422.

The upper housing member 410 has an upper surface 411 and a lower surface 412. A first port 441 and a third port 443 are formed into the upper surface 411. Each of the first and third ports 441, 443 have a seal cavity 445. Passages 413 extend from the first and third ports 441, 443 in the upper surface 411 to the lower surface 412. Annular rings 446 are formed in the lower surface 412 which engage the grooves 447 as discussed above. Pockets 454 are formed into the lower surface 412 surrounding the passage 413 that extends from the first port 441. As discussed above, the pockets 454 are symmetrically arranged about the passage 413 and the corresponding longitudinal axis A-A to enable application of a magnetic field generated by magnets 260.

Fastener passageways 448 extend through the upper housing member 410 from the upper surface 411 to the lower surface 412. In addition, fastening features 449 are formed in the upper housing member 410. The fastening features 449 may be counter bored holes, countersunk holes, or similar features which enable fastening the upper housing member 410 to the lower housing member 420. The lower housing member 420 may incorporate corresponding fastening features such as tapped holes which may receive fasteners installed in the fastening features 449.

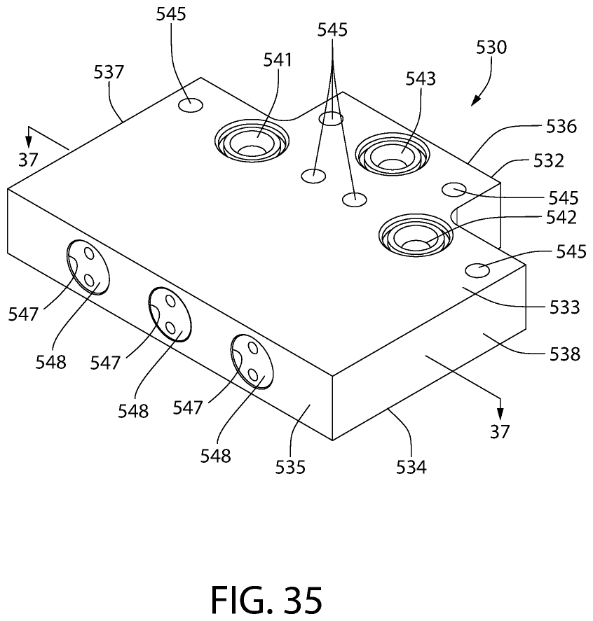

Turning to FIGS. 35-37, a fourth fluid flow component 530 as may be used in the fluid delivery module 1400 is shown. In the present embodiment, the fluid flow component 530 is a fluid mixer intended to mix two or more fluids and output a fluid mixture. The fluid flow component 530 may be functionally identical to the fluid flow component 130 and may have some component interchangeability between the two fluid flow components. As shown, the fluid flow component 530 is a passive component, but in other configurations it may be configured as an active component capable of actively altering fluid flow. The component 530 has a housing 532, the housing 532 having a top surface 533, bottom surface 534, front surface 535, rear surface 536, left surface 537, and right surface 538. As can be seen, the rear surface 536 is not planar, but instead comprises a projection which extends from adjacent portions of the rear surface 536.

The top surface 533 of the housing 532 comprises a first port 541, a second port 542, and a third port 543. The first and second ports 541, 542 are configured to receive fluid while the third port 543 is configured to output fluid. However, in some embodiments, different ones of the first, second, and third ports 541, 542, 543 may serve as inlets and outlets. In addition, it is conceived that there may be more than three ports to facilitate combining more than two fluids or splitting one or more fluids. Each of the ports 541, 542, 543 comprises a seal cavity 544 which is configured to receive a seal to facilitate connection with other components. The housing 532 further comprises a plurality of fastener passageways 545 that facilitate attachment of the housing 532 to the support structure 1402. In addition, the fastener passageways 545 can facilitate attachment of other flow components 104, 120 to the housing 532. The fastener passageways 545 may be through holes, threaded holes, or may be formed in any manner that permits attachment.

The bottom surface 534 of the housing 532 is configured to be in physical contact with the upper surface 1403 of the support structure 1402 when the fluid flow component 530 is mounted to the support structure 1402. However, in other embodiments, the upper surface 1403 may face the top surface 533 if the fluid flow component 530 is attached to another fluid flow component 104, 120, the other fluid flow component 104, 120 being directly coupled to the support structure 1402.

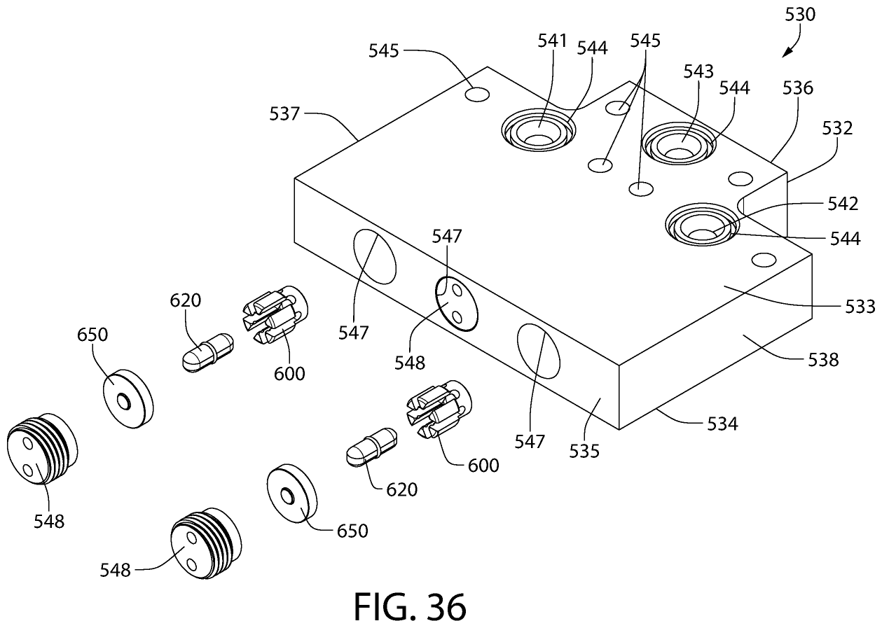

The front surface 535 and the left surface 537 collectively comprise a plurality of assembly ports 547. Each of the assembly ports 547 comprises a retention component 548 which provides a fluid-tight seal for the assembly ports 547 and retains any components installed in the assembly ports 547. For example, FIG. 36 illustrates an exploded view of the retention component 548 removed from the housing 532. A closure member 600, a magnet 620, and a stop member 650 are also shown. The stop member 650 is retained by the retention component 548 and also seals the assembly port 547 to prevent leakage of fluid through the assembly port 547.

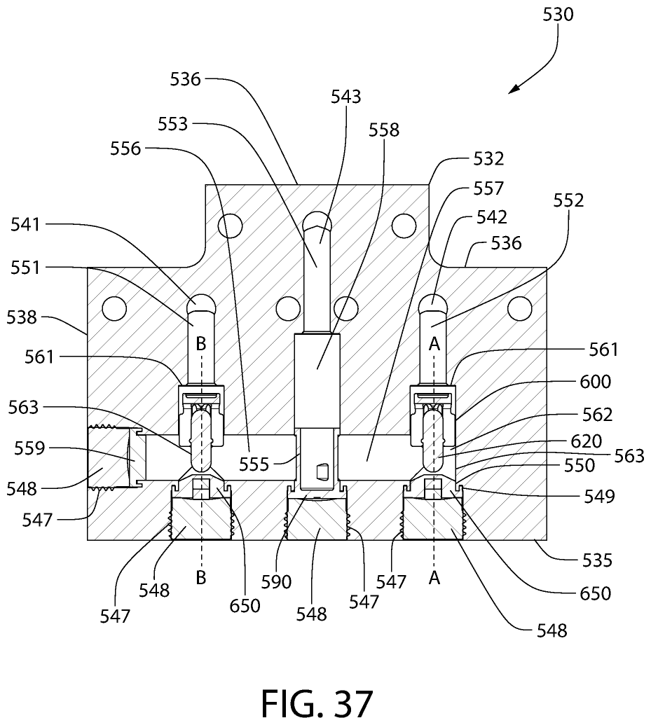

FIG. 37 illustrates a cross-section of the fluid flow component 530 in the assembled condition. The fluid flow component 530 has first, second, and third flow paths 551, 552, 553 extending from the first, second, and third ports 541, 542, 543 to a junction 555. A mixing element 590 is located at a junction 555. Thus, fluid can flow from the first port 541 through the first flow path 551 to the junction 555. Fluid can also flow from the second port 542 through the second flow path 552 to the junction 555. Fluid can flow from the junction 555 through the third flow path 553 to the third port 543. The first, second, and third flow paths 551, 552, 553 meet to form a T shape at the junction 555. The first, second, and third flow paths 551, 552, 553 collectively form a flow path extending from inlets at the first and second ports 541, 542 to an outlet at the third port 543.

More specifically, the first flow path 551 has a first conduit 556, the first conduit 556 being immediately adjacent the junction 555. The second flow path 552 has a second conduit 557, the second conduit 557 being immediately adjacent the junction 555. The third flow path 553 has a third conduit 558, the third conduit 558 being immediately adjacent the junction 555. The first and second conduits 556, 557 of the first and second flow paths 551, 552 are co-linear while the third conduit 558 of the third flow path 553 is perpendicular to the first and second conduits 556, 557 of the first and second flow paths 551, 552. Thus, fluid flows along the first and second flow paths 551, 552 and meets at the junction 555. Fluid then proceeds from the junction 555 via the third conduit 558 of the third flow path 553 at a right angle from both of the first and second conduits 556, 557 of the first and second flow paths 551, 552.

Check valves are located in the first and second flow paths 551, 552 to prevent back-flow of the fluids supplied to the first and second ports 541, 542. Check valves are formed by a seat 561 formed in the housing 532, a closure member 600, and, optionally, a stop member 650. In some implementations, the stop member 650 may be omitted and the housing 532 may incorporate some or all of the features of the stop member 650. The seat 561 may be an integrally formed, monolithic, portion of the housing 532 or may be a separate component which is installed into or coupled to the housing 532. The seat 561 may have a flat surface or may incorporate separate sealing members or features to promote effective sealing with the closure member 600. Thus, the check valves prevent back-flow from the third port 543 to exit either of the first or second ports 541, 542 as a result of the sealing of the closure member 600 against the seat 561.

The closure member 600 is located within a cavity 562 in the housing 532 which is accessible via an adjacent assembly port 547. The closure member 600 is slidably movable within the cavity 562 along a longitudinal axis A-A, B-B and is configured to prevent fluid flow when the closure member 600 is in contact with the seat 561. Preferably, the closure member 600 moves cither concentric with or parallel to its respective longitudinal axis A-A, B-B. The longitudinal axes A-A, B-B extend along their respective cavities 562. The seats 561 are preferably concentric about their respective longitudinal axes A-A, B-B and the cavities 562 are concentric about their respective longitudinal axes A-A, B-B. The cavities 562 each have a cylindrical inner surface 563 which is concentric about their respective longitudinal axis A-A, B-B. Similarly, the stop members 650 are aligned with and symmetric about their respective longitudinal axes A-A, B-B.

Each of the closure members 600 is installed via an assembly port 547 and retained by a retention component 548. The retention components 548 may be threaded and the assembly port 547 may have corresponding threads to allow securing the stop member 650 within the assembly port 547. The stop member 650 may form a seal. Alternately, in other assembly ports 547 a seal 559 may be used to seal the assembly port 547. Similarly, the mixing element 590 may also incorporate features which provide a sealing function to seal the assembly port 547. Alternatively, other known retention means may be utilized as desired. In yet other configurations, the stop member 650 may be substituted for a seal 559.

The assembly port 547 located on the left side 537 of the housing 532 does not have a component inserted therein, but instead includes a seal 559 to prevent leakage. The seal 559 has a primary purpose to seal the assembly port 547. However, it is possible to omit the seal 559 and utilize one or more assembly ports 147 to enable additional fluid connections. As can be seen, each of the mixing element 590, stop members 650, and seal 559 engage an annular rib 549 within the assembly ports 547. This annular rib 549 ensures that sealing is achieved and provides an axial constraint for the mixing element 590, stop members 650, and seal 559. Thus, the annular rib 549 and a corresponding annular groove 550 ensure that the components are properly retained within the assembly port 547 and seal to prevent fluid leakage.

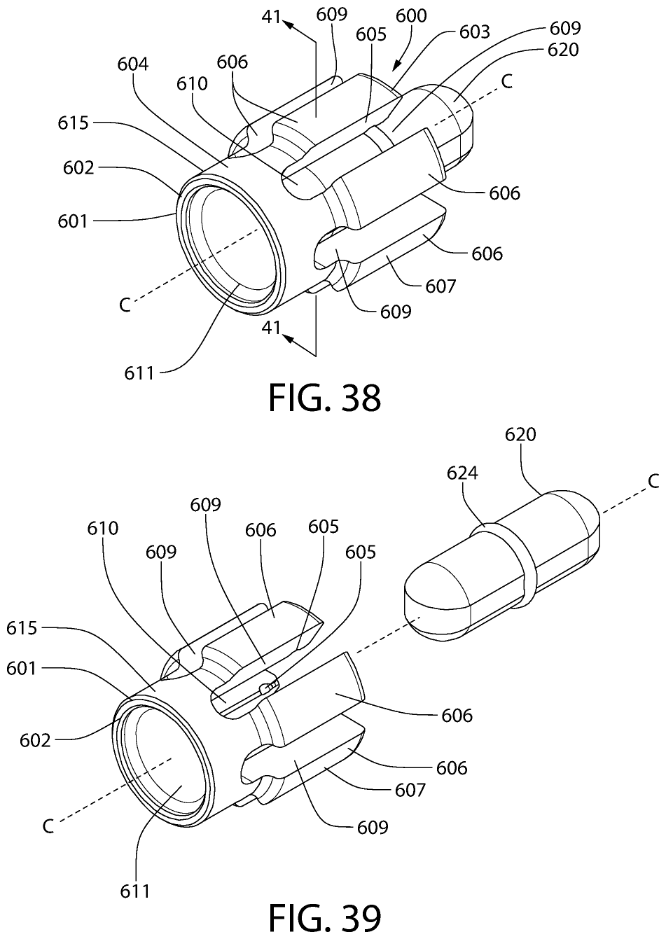

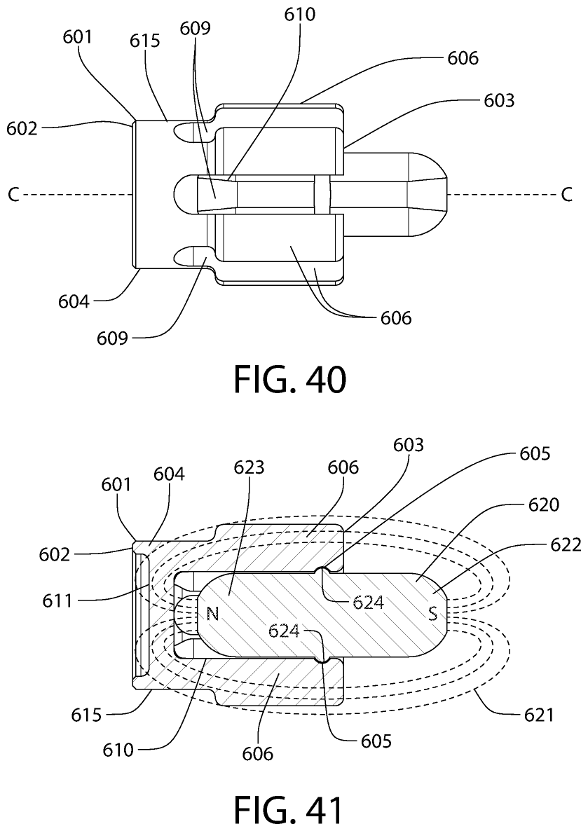

FIGS. 38-41 illustrate the closure member 600 in greater detail. The closure member 600 has a body 615 that extends from a first end 601 to a second end 603 along a longitudinal axis C-C. The closure member 600 has a sealing surface 602 at the first end 601, formed on a first portion 604 of the closure member 600. A plurality of protuberances 606 extend from the first portion 604 along the longitudinal axis C-C and radially outward from the longitudinal axis C-C. Each of the plurality of protuberances 606 has an arcuate outer portion 607 which collectively define a cylinder having a first outer diameter. Otherwise stated, the arcuate outer portions 607 preferably have the same radius and are centered about the longitudinal axis C-C. This allows the arcuate outer portions 607 to engage the inner surface 563 of the cavity 562. The plurality of protuberances 606 are elongate with respect to the longitudinal axis C-C. Preferably, the first outer diameter of the protuberances 606 is greater than a second outer diameter of the first portion 604. However, in other implementations, the first and second outer diameters may be equal or the first outer diameter may be less than the second outer diameter.

Gaps 609 are formed between adjacent ones of the plurality of protuberances 606. This allows fluid to flow past the protuberances 606 while the arcuate outer portions 607 of the plurality of protuberances 606 engage the inner surface 563 of the cavity 562. Thus, the arcuate outer portions 607 of the plurality of protuberances 606 maintain the closure member 600 within the cavity 662. The arcuate outer portions 607 of the plurality of protuberances 606 are sized so that the closure member 600 is prevented from moving laterally or radially with respect to the longitudinal axis A-A, B-B. Otherwise stated, the closure member 600 is free to move along the respective longitudinal axis A-A, B-B while being prevented from moving radially. The longitudinal axis A-A, B-B is substantially co-axial with the longitudinal axis C-C when the closure member 600 is within the cavity 562. Preferably, the first portion 604 has a diameter which is less than or equal to a diameter of the arcuate outer portions 607 of the plurality of protuberances 606 as noted above.

The closure member 600 further comprises a cavity 610 formed within and defined by the plurality of protuberances 606 and the first portion 604. The cavity 610 is formed at the second end 603 and is open at the second end 603 and open via the gaps 609 between the protuberances 606. The cavity 610 is configured to receive the magnet 620 discussed above. Each of the protuberances 606 has a groove 605 formed therein, the grooves 605 located within the cavity 610. The grooves 605 receive a protuberance 624 formed on the magnet 620, allowing the magnet 620 to be retained within the cavity 610 by the interaction between the grooves 605 and the protuberance 624. Preferably, the protuberance 624 is formed as a ring to aid retention of the magnet 620 within the grooves 605.

The body 615 further has a recess 611 formed at the first end 601. The recess 611 is formed within the first portion 604 but does not connect with the cavity 610. Instead, the first portion 604 forms a barrier between the recess 610 and the cavity 610. This ensures that no fluid can escape past the sealing surface 602 when the closure member 200 is in contact with the seat 561. The recess 211 and the cavity 210 are symmetric about the longitudinal axis C-C.

The magnet 620 has a magnetic field 621 which extends from a south pole 622 to a north pole 623. Thus, the magnet 620 generates the magnetic field 621. The south pole 622 is closer to the second end 603 while the north pole 623 is closer to the first end 601. Optionally, the orientation of the magnet 620 may be reversed as desired. Furthermore, more than one magnet 620 may be utilized or other magnetic materials may be used. The magnetic field 621 forms a portion of the total magnetic field of the fluid flow component 530, but additional magnetic fields from other sources may form a portion of the total magnetic field of the fluid flow component. Optionally, the magnet 620 may be encapsulated in a non-reactive material such as a polymer, and may incorporate a protuberance 624 or other feature to retain the magnet 620 within the cavity 610.

In other implementations, a magnetic material may be utilized for the magnet 620 or other materials may be substituted. For example, iron, nickel, cobalt, or a rare-earth metal may be used. Alternately, copper, gold, calcium, aluminum, or similar materials or alloys may be utilized for their properties as diamagnetic or paramagnetic materials. In yet other implementations, an electromagnet may be utilized in place of the magnet 620.

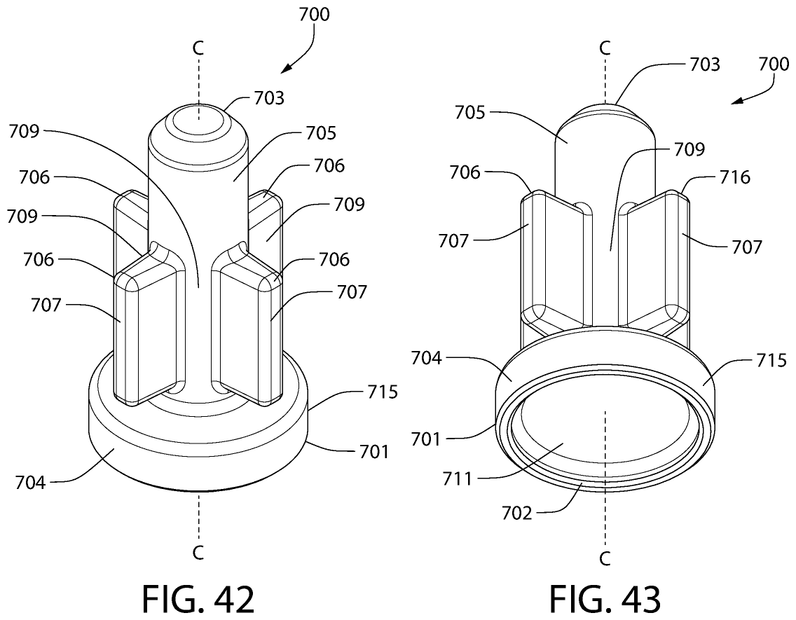

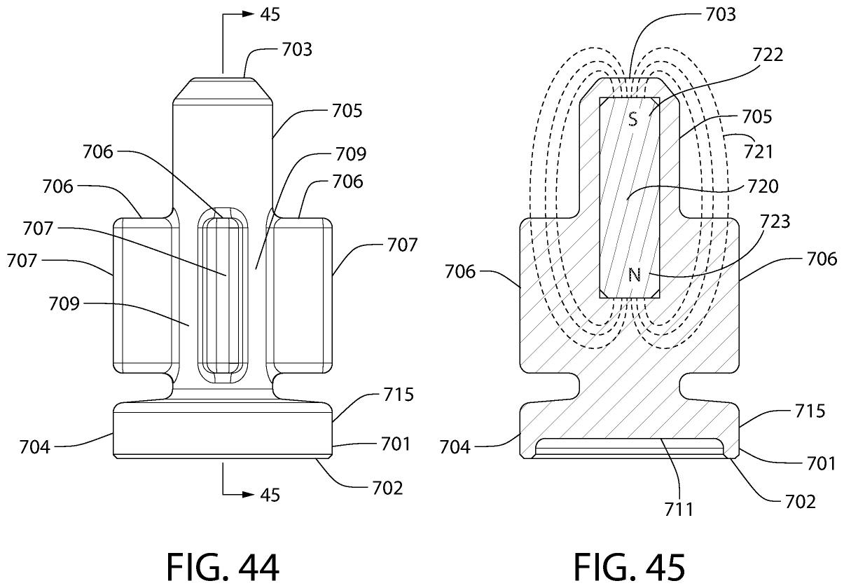

FIGS. 42-45 illustrate another embodiment of a closure member 700 as may be used in the fluid flow component 530. The closure member 700 has a body 715 that extends from a first end 701 to a second end 703 along a longitudinal axis C-C. The closure member 700 has a sealing surface 702 at the first end 701, formed on an enlarged portion 704 of the closure member 700. A shaft portion 705 extends from the enlarged portion 704 to the second end 703. A plurality of protuberances 706 extend from the shaft portion 705. The plurality of protuberances 706 are formed as fins and have an arcuate outer portion 707 that generally define a cylinder. The arcuate outer portions 707 preferably have the same radius and are centered about the longitudinal axis C-C. This allows the arcuate outer portions 707 to engage the inner surface 563 of the cavity 562. Preferably, the fins are aligned with the longitudinal axis C-C and are spaced from the enlarged portion 704. The plurality of protuberances 706 are elongate with respect to the longitudinal axis C-C. The plurality of protuberances 706 are spaced and isolated from the enlarged portion 704.

Gaps 709 are formed between adjacent ones of the plurality of protuberances 706. This allows fluid to flow past the plurality of protuberances 706 while the arcuate outer portions 707 of the plurality of protuberances 706 engage the inner surface 563 of the cavity 562. Thus, the arcuate outer portions 707 of the plurality of protuberances 706 maintain the closure member 700 within the cavity 562. The arcuate outer portions 707 of the plurality of protuberances 706 are sized so that the closure member 700 is prevented from moving laterally or radially with respect to the longitudinal axis A-A, B-B. Otherwise stated, the closure member 700 is free to move along the respective longitudinal axis A-A, B-B while being prevented from moving radially. The longitudinal axis A-A, B-B is substantially co-axial with the longitudinal axis C-C when the closure member 700 is within the cavity 562. Preferably, the enlarged portion 704 has a diameter which is equal to a diameter of the arcuate outer portions 707 of the plurality of protuberances 706. In other implementations, the diameter of the arcuate outer portions 707 may be less than or greater than the diameter of the enlarged portion 704.

The closure member 700 further comprises a cavity 710 formed within the body 715. The cavity 710 is illustrated as being closed with a magnet 720 therein, but the cavity 710 may be formed in a variety of ways. For instance, the cavity 710 may be plugged or welded shut or the magnet 720 may be overmolded when the closure member 700 is formed. Optionally, the cavity 710 may have an opening at either the first or second ends 701, 703 similar to the closure member 200 discussed above.

The body 715 has a recess 711 formed at the first end 701. Optionally, the recess 711 and the cavity 710 may be isolated from one another as illustrated or may be fluidly connected if the cavity 710 extends to the recess 711. Optionally, the cavity 710 may be closed by inserting a plug which isolates the cavity 710 from the recess 711 as illustrated in the closure member 200. The recess 711 and the cavity 710 are symmetric about the longitudinal axis C-C. The magnet 720 is located within the cavity 710.

The magnet 720 has a magnetic field 721 which extends from a south pole 722 to a north pole 723. Thus, the magnet 720 generates the magnetic field 721. The south pole 722 is adjacent the second end 703 while the north pole 723 is adjacent the first end 701. Optionally, the orientation of the magnet 720 may be reversed as desired. Furthermore, more than one magnet 720 may be utilized or other magnetic materials may be used. The magnetic field 721 forms a portion of the total magnetic field of the fluid flow component 530, but additional magnetic fields from other sources may form a portion of the total magnetic field of the fluid flow component.

In other implementations, a magnetic material may be utilized for the magnet 720 or other materials may be substituted. For example, iron, nickel, cobalt, or a rare-earth metal may be used. Alternately, copper, gold, calcium, aluminum, or similar materials or alloys may be utilized for their properties as diamagnetic or paramagnetic materials. In yet other implementations, an electromagnet may be utilized in place of the magnet 720.

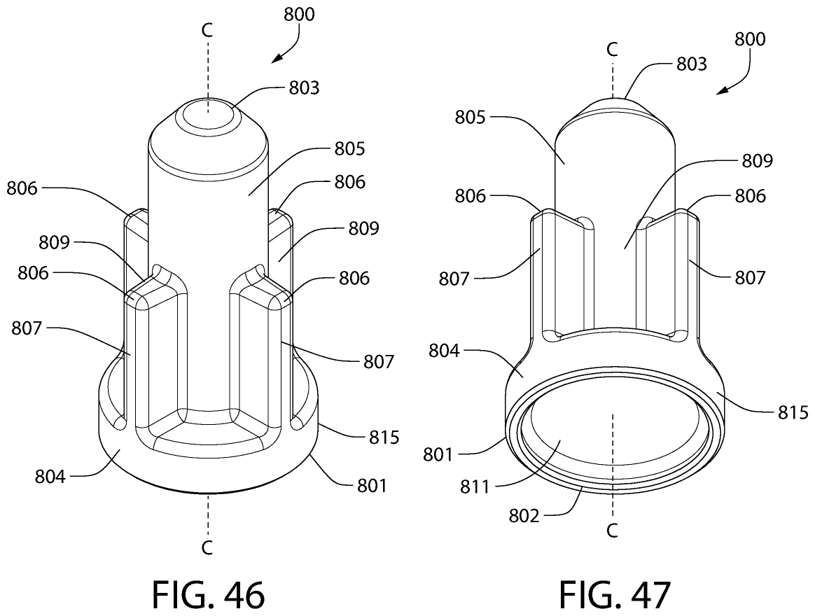

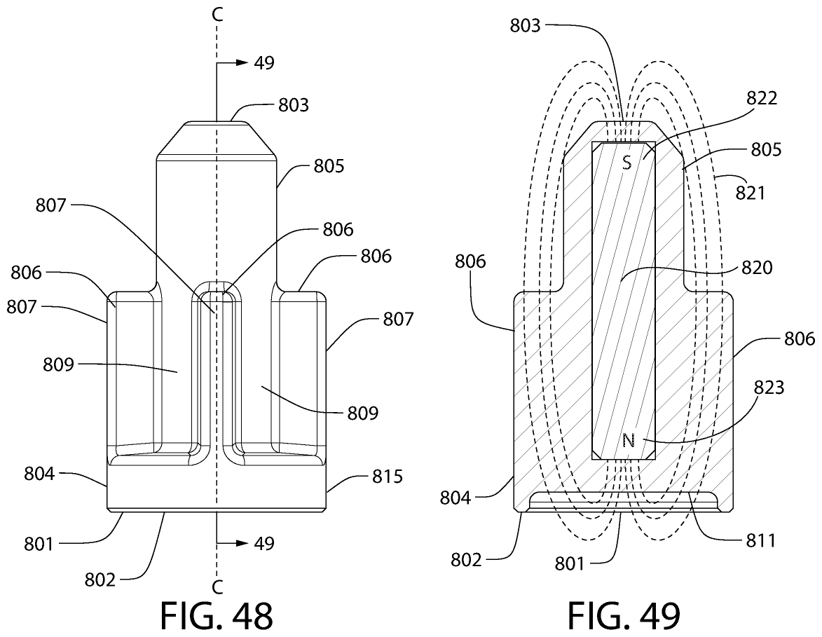

FIGS. 46-49 illustrate another embodiment of a closure member 800 as may be used in the fluid flow component 530. The closure member 800 has a body 815 that extends from a first end 801 to a second end 803 along a longitudinal axis C-C. The closure member 800 has a sealing surface 802 at the first end 801, formed on an enlarged portion 804 of the closure member 800. A shaft portion 805 extends from the enlarged portion 804 to the second end 803. A plurality of protuberances 806 extend from the shaft portion 805. The plurality of protuberances 806 are formed as fins and have an arcuate outer portion 807 that generally define a cylinder. The arcuate outer portions 807 preferably have the same radius and are centered about the longitudinal axis C-C. This allows the arcuate outer portions 807 to engage the inner surface 563 of the cavity 562. Preferably, the fins are aligned with the longitudinal axis C-C and are spaced from the enlarged portion 804. The plurality of protuberances 806 are elongate with respect to the longitudinal axis C-C. The plurality of protuberances 806 also extend from the enlarged portion 804 rather than being spaced and isolated from the enlarged portion 704 as shown in the closure member 700.

Gaps 809 are formed between adjacent ones of the plurality of protuberances 806. This allows fluid to flow past the plurality of protuberances 806 while the arcuate outer portions 807 of the plurality of protuberances 806 engage the inner surface 563 of the cavity 562. Thus, the arcuate outer portions 807 of the plurality of protuberances 806 maintain the closure member 800 within the cavity 562. The arcuate outer portions 807 of the plurality of protuberances 806 are sized so that the closure member 800 is prevented from moving laterally or radially with respect to the longitudinal axis A-A, B-B. Otherwise stated, the closure member 800 is free to move along the respective longitudinal axis A-A, B-B while being prevented from moving radially. The longitudinal axis A-A, B-B is substantially co-axial with the longitudinal axis C-C when the closure member 800 is within the cavity 562. Preferably, the enlarged portion 804 has a diameter which is equal to a diameter of the arcuate outer portions 807 of the plurality of protuberances 806. In other implementations, the diameter of the arcuate outer portions 807 may be less than or greater than the diameter of the enlarged portion 804.

The closure member 800 further comprises a cavity 810 formed within the body 815. The cavity 810 is illustrated as being closed with a magnet 820 therein, but the cavity 810 may be formed in a variety of ways. For instance, the cavity 810 may be plugged or welded shut or the magnet 820 may be overmolded when the closure member 800 is formed. Optionally, the cavity 810 may have an opening at either the first or second ends 801, 803 similar to the closure member 200 discussed above.

The body 815 has a recess 811 formed at the first end 801. Optionally, the recess 811 and the cavity 810 may be isolated from one another as illustrated or may be fluidly connected if the cavity 810 extends to the recess 811. Optionally, the cavity 810 may be closed by inserting a plug which isolates the cavity 810 from the recess 811 as illustrated in the closure member 200. The recess 811 and the cavity 810 are symmetric about the longitudinal axis C-C. The magnet 820 is located within the cavity 810.

The magnet 820 has a magnetic field 821 which extends from a south pole 822 to a north pole 823. Thus, the magnet 820 generates the magnetic field 821. The south pole 822 is adjacent the second end 803 while the north pole 823 is adjacent the first end 801. Optionally, the orientation of the magnet 820 may be reversed as desired. Furthermore, more than one magnet 820 may be utilized or other magnetic materials may be used. The magnetic field 821 forms a portion of the total magnetic field of the fluid flow component 530, but additional magnetic fields from other sources may form a portion of the total magnetic field of the fluid flow component.

In other implementations, a magnetic material may be utilized for the magnet 820 or other materials may be substituted. For example, iron, nickel, cobalt, or a rare-earth metal may be used. Alternately, copper, gold, calcium, aluminum, or similar materials or alloys may be utilized for their properties as diamagnetic or paramagnetic materials. In yet other implementations, an electromagnet may be utilized in place of the magnet 820.

It is conceived that the disclosed fluid flow components 130, 300, 400, 530, comprising one or more check valves formed by a cavity, seat, and closure member, may be implemented in the apparatuses 100. These apparatuses 100 may also incorporate additional fluid flow components not disclosed herein that incorporate analogous check valves. The stop member features may be integrally formed into the housing or may be a separate component, depending on assembly requirements, design requirements, and packaging requirements. Furthermore, more than one check valve may be utilized in a single fluid flow component as desired. No mechanical biasing element is required to provide a seal between the closure member and the corresponding seat. Instead, magnetic biasing is provided by magnets or other components which are arranged in these or similar manners. No springs, levers, weights, or other mechanically biased features are required to ensure closing of the check valve.

### Exemplary Claim Set

Exemplary claim 1: A fluid flow component, the fluid flow component comprising: a housing comprising: an inlet; an outlet; a cavity, a longitudinal axis extending along the cavity; a seat within the cavity; and a flow path extending from the inlet to the cavity and from the cavity to the outlet; and a closure member slidably movable within the cavity of the housing, the closure member configured to engage the seat to prevent fluid flow through the flow path in a reverse direction; and wherein a magnetic field biases the closure member into contact with the seat.

Exemplary claim 2: The fluid flow component of claim 1 wherein the magnetic field is configured to repel the closure member.

Exemplary claim 3: The fluid flow component of claim 1 or claim 2 further comprising a first magnet, the first magnet generating a first portion of the magnetic field.

Exemplary claim 4: The fluid flow component of claim 3 wherein the first magnet is spaced and isolated from the closure member.

Exemplary claim 5: The fluid flow component of claim 3 or claim 4 wherein the closure member comprises a second magnet.

Exemplary claim 6: The fluid flow component of claim 5 wherein the second magnet generates a second portion of the magnetic field.

Exemplary claim 7: The fluid flow component of claim 6 wherein the first portion of the magnetic field comprises a first plurality of field lines and the second portion of the magnetic field comprises a second plurality of field lines, the first plurality of field lines spaced and isolated from the second plurality of field lines.

Exemplary claim 8: The fluid flow component of any one of claims 1 to 7 wherein the closure member comprises a cavity, a second magnet located within the cavity of the closure member.

Exemplary claim 9: The fluid flow component of claim 8 wherein the closure member further comprises a sealing element which seals the cavity of the closure member.

Exemplary claim 10: The fluid flow component of any one of claims 1 to 9 wherein the cavity of the housing comprises an inner surface and the closure member comprises a plurality of protuberances, the plurality of protuberances engaging the inner surface.

Exemplary claim 11: The fluid flow component of claim 10 wherein the inner surface of the cavity of the housing has a constant diameter with respect to the longitudinal axis.

Exemplary claim 12: The fluid flow component of claim 10 or claim 11 wherein the plurality of protuberances prevent lateral movement of the closure member with respect to the longitudinal axis.

Exemplary claim 13: The fluid flow component of any one of claims 1 to 12 wherein the fluid flow component is free of mechanical biasing elements.

Exemplary claim 14: The fluid flow component of any one of claims 1 to 13 wherein the seat is concentric about the longitudinal axis.

Exemplary claim 15: The fluid flow component of claim 14 wherein the closure member moves within the cavity of the housing in a direction parallel to the longitudinal axis.

Exemplary claim 16: The fluid flow component of any one of claims 1 to 15 further comprising a stop member, the stop member aligned with the longitudinal axis.

Exemplary claim 17: The fluid flow component of claim 16 wherein the stop member comprises a first magnet.

Exemplary claim 18: The fluid flow component of claim 16 or claim 17 wherein the stop member is symmetric about the longitudinal axis.

Exemplary claim 19: The fluid flow component of any one of claims 16 to 18 wherein the stop member limits motion of the closure member along the longitudinal axis.

Exemplary claim 20: The fluid flow component of any one of claims 16 to 19 wherein the stop member is secured to the housing.

Exemplary claim 21: The fluid flow component of any one of claims 16 to 20 wherein the stop member is formed by a portion of the housing.

Exemplary claim 22: The fluid flow component of any one of claims 1 to 15 wherein the housing comprises a first pocket, a second pocket, and a third pocket, a first magnet within the first pocket, a third magnet within the second pocket, and a fourth magnet within the third pocket.

Exemplary claim 23: The fluid flow component of claim 22 wherein the closure member comprises a second magnet.

Exemplary claim 24: The fluid flow component of claim 23 wherein each of the first, second, third, and fourth magnets comprise a north pole and a south pole, each of the south poles of the first, second, third, and fourth magnets having the same orientation with respect to the longitudinal axis.

Exemplary claim 25: The fluid flow component of any one of claims 22 to 24 wherein the first, second, and third pockets are arranged at an equal distance from the longitudinal axis.

Exemplary claim 26: A system for processing articles, the system comprising: a first fluid flow component, the fluid flow component comprising: a housing comprising: an inlet comprising a first port, the first port comprising a seal cavity; an outlet comprising a second port, the second port comprising a seal cavity; a cavity, a longitudinal axis extending along the cavity; a seat within the cavity; and a flow path extending from the inlet to the cavity and from the cavity to the outlet; and a closure member slidably movable within the cavity of the housing, the closure member configured to engage the seat to prevent fluid flow through the flow path in a reverse direction; and a second fluid flow component, the fluid flow component comprising a first port and a second port, a flow path extending from the first port to the second port, each of the first port and the second port comprising a seal cavity; and a seal; wherein the second port of the second fluid flow component is aligned with the first port of the first fluid flow component, the seal located within the seal cavity of the second port of the second fluid flow component and the seal cavity of the first port of the first fluid flow component; and wherein a magnetic field biases the closure member into contact with the seat.

Exemplary claim 27: The system of claim 26 wherein the magnetic field is configured to repel the closure member.

Exemplary claim 28: The system of claim 26 or claim 27 further comprising a first magnet, the first magnet generating a first portion of the magnetic field.

Exemplary claim 29: The system of claim 28 wherein the first magnet is spaced and isolated from the closure member.

Exemplary claim 30: The system of claim 28 or claim 29 wherein the closure member comprises a second magnet.

Exemplary claim 31: The system of claim 30 wherein the second magnet generates a second portion of the magnetic field.

Exemplary claim 32: The system of claim 31 wherein the first portion of the magnetic field comprises a first plurality of field lines and the second portion of the magnetic field comprises a second plurality of field lines, the first plurality of field lines spaced and isolated from the second plurality of field lines.

Exemplary claim 33: The system of any one of claims 26 to 32 wherein the closure member comprises a cavity, a second magnet located within the cavity of the closure member.

Exemplary claim 34: The system of claim 33 wherein the closure member further comprises a sealing element which seals the cavity of the closure member.

Exemplary claim 35: The system of any one of claims 26 to 34 wherein the cavity of the housing comprises an inner surface and the closure member comprises a plurality of protuberances, the plurality of protuberances engaging the inner surface.

Exemplary claim 36: The system of claim 35 wherein the inner surface of the cavity of the housing has a constant diameter with respect to the longitudinal axis.

Exemplary claim 37: The system of claim 35 or claim 36 wherein the plurality of protuberances prevent lateral movement of the closure member with respect to the longitudinal axis.

Exemplary claim 38: The system of any one of claims 26 to 37 wherein the first fluid flow component is free of mechanical biasing elements.

Exemplary claim 39: The system of any one of claims 26 to 38 wherein the seat is concentric about the longitudinal axis.

Exemplary claim 40: The system of claim 39 wherein the closure member moves within the cavity of the housing in a direction parallel to the longitudinal axis.

Exemplary claim 41: The system of any one of claims 26 to 15 wherein the first fluid flow component further comprises a stop member, the stop member aligned with the longitudinal axis.

Exemplary claim 42: The system of claim 41 wherein the stop member comprises a first magnet.

Exemplary claim 43: The system of claim 41 or claim 42 wherein the stop member is symmetric about the longitudinal axis.

Exemplary claim 44: The system of any one of claims 41 to 43 wherein the stop member limits motion of the closure member along the longitudinal axis.

Exemplary claim 45: The system of any one of claims 41 to 44 wherein the stop member is secured to the housing.

Exemplary claim 46: The system of any one of claims 41 to 45 wherein the stop member is formed by a portion of the housing.

Exemplary claim 47: The system of any one of claims 26 to 46 wherein the housing comprises a first pocket, a second pocket, and a third pocket, a first magnet within the first pocket, a third magnet within the second pocket, and a fourth magnet within the third pocket.

Exemplary claim 48: The system of claim 47 wherein the closure member comprises a second magnet.

Exemplary claim 49: The system of claim 48 wherein each of the first, second, third, and fourth magnets comprise a north pole and a south pole, each of the south poles of the first, second, third, and fourth magnets having the same orientation with respect to the longitudinal axis.

Exemplary claim 50: The system of any one of claims 47 to 49 wherein the first, second, and third pockets are arranged at an equal distance from the longitudinal axis.

Exemplary claim 51: A fluid flow component, the fluid flow component comprising: a housing comprising: an inlet; an outlet; a cavity, a longitudinal axis extending along the cavity; a seat within the cavity; and a flow path extending from the inlet to the cavity and from the cavity to the outlet; a stop member comprising a first magnet; and a closure member slidably movable within the cavity of the housing, the closure member comprising a second magnet, the closure member configured to engage the seat to prevent fluid flow through the flow path in a reverse direction; and wherein a magnetic field generated by the first and second magnets biases the closure member into contact with the seat.

Exemplary claim 52: The fluid flow component of claim 51 wherein the magnetic field is configured to repel the closure member.

Exemplary claim 53: The fluid flow component of claim 51 or claim 52 wherein the first magnet generates a first portion of the magnetic field.

Exemplary claim 54: The fluid flow component of any one of claims 51 to 53 wherein the first magnet is spaced and isolated from the closure member.

Exemplary claim 55: The fluid flow component of any one of claims 51 to 54 wherein the second magnet generates a second portion of the magnetic field.

Exemplary claim 56: The fluid flow component of any one of claims 51 to 55 wherein a first portion of the magnetic field comprises a first plurality of field lines and a second portion of the magnetic field comprises a second plurality of field lines, the first plurality of field lines spaced and isolated from the second plurality of field lines.

Exemplary claim 57: The fluid flow component of any one of claims 51 to 57 wherein the closure member comprises a cavity, the second magnet located within the cavity of the closure member.

Exemplary claim 58: The fluid flow component of claim 57 wherein the closure member further comprises a sealing element which seals the cavity of the closure member.

Exemplary claim 59: The fluid flow component of any one of claims 51 to 58 wherein the cavity of the housing comprises an inner surface and the closure member comprises a plurality of protuberances, the plurality of protuberances engaging the inner surface.

Exemplary claim 60: The fluid flow component of claim 59 wherein the inner surface of the cavity of the housing has a constant diameter with respect to the longitudinal axis.

Exemplary claim 61: The fluid flow component of claim 59 or claim 60 wherein the plurality of protuberances prevent lateral movement of the closure member with respect to the longitudinal axis.

Exemplary claim 62: The fluid flow component of any one of claims 51 to 61 wherein the fluid flow component is free of mechanical biasing elements.

Exemplary claim 63: The fluid flow component of any one of claims 51 to 62 wherein the seat is concentric about the longitudinal axis.

Exemplary claim 64: The fluid flow component of claim 63 wherein the closure member moves within the cavity of the housing in a direction parallel to the longitudinal axis.

Exemplary claim 65: The fluid flow component of any one of claims 51 to 64 wherein the stop member is aligned with the longitudinal axis.

Exemplary claim 66: The fluid flow component of claim 65 wherein the stop member is symmetric about the longitudinal axis.

Exemplary claim 67: The fluid flow component of claim 65 or claim 66 wherein the stop member limits motion of the closure member along the longitudinal axis.

Exemplary claim 68: The fluid flow component of any one of claims 65 to 67 wherein the stop member is secured to the housing.

Exemplary claim 69: The fluid flow component of any one of claims 65 to 68 wherein the stop member is formed by a portion of the housing.

Exemplary claim 70: The fluid flow component of any one of claims 51 to 69 wherein the housing comprises a first pocket, a second pocket, and a third pocket, a first magnet within the first pocket, a third magnet within the second pocket, and a fourth magnet within the third pocket.

Exemplary claim 71: The fluid flow component of claim 70 wherein each of the first, second, third, and fourth magnets comprise a north pole and a south pole, each of the south poles of the first, second, third, and fourth magnets having the same orientation with respect to the longitudinal axis.

Exemplary claim 72: The fluid flow component of claim 70 or claim 71 wherein the first, second, and third pockets are arranged at an equal distance from the longitudinal axis.

Exemplary claim 73: A closure member for a check valve comprising: a body extending from a first end to a second end along a longitudinal axis, the body having a cavity formed therein; an enlarged portion formed at the first end of the body, the enlarged portion comprising a sealing surface; a shaft portion extending from the enlarged portion to the second end; a plurality of protuberances extending from the shaft portion; and a magnet located within the cavity.

Exemplary claim 74: The closure member of claim 73 wherein each of the plurality of protuberances has an arcuate outer portion.

Exemplary claim 75: The closure member of claim 74 wherein the plurality of protuberances form portions of a first annular ring and a second annular ring.

Exemplary claim 76: The closure member of any one of claims 73 to 75 wherein the cavity is formed into the enlarged portion of the body.

Exemplary claim 77: The closure member of any one of claims 73 to 76 wherein adjacent ones of the plurality of protuberances are separated by gaps.

Exemplary claim 78: The closure member of any one of claims 73 to 77 wherein the plurality of protuberances collectively define an outer diameter which is greater than an outer diameter of the enlarged portion.

Exemplary claim 79: The closure member of any one of claims 73 to 78 wherein the enlarged portion comprises a recess, the sealing surface surrounding the recess.

Exemplary claim 80: The closure member of any one of claims 73 to 79 wherein the cavity is formed into the recess and extends into the shaft portion.

Exemplary claim 81: The closure member of claim 73 wherein the plurality of protuberances are fins.

Exemplary claim 82: The closure member of claim 81 wherein the plurality of protuberances are elongate with respect to the longitudinal axis.

Exemplary claim 83: The closure member of claim 81 or claim 82 wherein the plurality of protuberances extend from the enlarged portion of the body.

Exemplary claim 84: The closure member of claim 81 or claim 82 wherein the plurality of protuberances are spaced and isolated from the enlarged portion.

Exemplary claim 85: The closure member of any one of claims 81 to 84 wherein the plurality of protuberances collectively define an outer diameter which is equal to an outer diameter of the enlarged portion.

Exemplary claim 86: A closure member for a check valve comprising: a body extending from a first end to a second end along a longitudinal axis; a first portion formed at the first end of the body comprising a sealing surface; a plurality of protuberances extending from the first portion along the longitudinal axis, the plurality of protuberances defining a cavity; and a magnet located within the cavity.

Exemplary claim 87: The closure member of claim 86 wherein the plurality of protuberances have a first outer diameter and the first portion has a second outer diameter, the first outer diameter greater than the second outer diameter.

Exemplary claim 88: The closure member of claim 86 or claim 87 wherein the plurality of protuberances collectively define a cylinder.

Exemplary claim 89: The closure member of any one of claims 86 to 88 wherein the plurality of protuberances are elongate with respect to the longitudinal axis.

Exemplary claim 90: The closure member of any one of claims 86 to 89 wherein each of the plurality of protuberances comprises a groove, the groove configured to engage a protuberance of the magnet.

Exemplary claim 91: The closure member of any one of claims 86 to 90 wherein the cavity is open at the second end of the body.

Exemplary claim 92: The closure member of any one of claims 86 to 91 wherein the cavity is open between adjacent ones of the plurality of protuberances.

While the invention has been described with respect to specific examples including presently preferred modes of carrying out the invention, those skilled in the art will appreciate that there are numerous variations and permutations of the above-described systems and techniques. It is to be understood that other embodiments may be utilized, and structural and functional modifications may be made without departing from the scope of the present invention. Thus, the spirit and scope of the invention should be construed broadly as set forth in the appended claims.

What is claimed is:

1. A fluid flow component, the fluid flow component comprising:
a housing comprising:
an inlet;
an outlet;
a cavity, a longitudinal axis extending along the cavity;
a seat within the cavity; and
a flow path extending from the inlet to the cavity and from the cavity to the outlet; and
a closure member slidably movable within the cavity of the housing, the closure member configured to engage the seat to prevent fluid flow through the flow path in a reverse direction; and
wherein a magnetic field biases the closure member into contact with the seat.

2. The fluid flow component of claim 1 wherein the magnetic field is configured to repel the closure member.

3. The fluid flow component of claim 1 or claim 2 further comprising a first magnet, the first magnet generating a first portion of the magnetic field.

4. The fluid flow component of claim 3 wherein the first magnet is spaced and isolated from the closure member.

5. The fluid flow component of claim 3 or claim 4 wherein the closure member comprises a second magnet.

6. The fluid flow component of claim 5 wherein the second magnet generates a second portion of the magnetic field.

7. The fluid flow component of claim 6 wherein the first portion of the magnetic field comprises a first plurality of field lines and the second portion of the magnetic field comprises a second plurality of field lines, the first plurality of field lines spaced and isolated from the second plurality of field lines.

8. The fluid flow component of any one of claims 1 to 7 wherein the closure member comprises a cavity, a second magnet located within the cavity of the closure member.

9. The fluid flow component of claim 8 wherein the closure member further comprises a sealing element which seals the cavity of the closure member.

10. The fluid flow component of any one of claims 1 to 9 wherein the cavity of the housing comprises an inner surface and the closure member comprises a plurality of protuberances, the plurality of protuberances engaging the inner surface.

11. The fluid flow component of claim 10 wherein the inner surface of the cavity of the housing has a constant diameter with respect to the longitudinal axis.

12. The fluid flow component of claim 10 or claim 11 wherein the plurality of protuberances prevent lateral movement of the closure member with respect to the longitudinal axis.

13. The fluid flow component of any one of claims 1 to 12 wherein the fluid flow component is free of mechanical biasing elements.

14. The fluid flow component of any one of claims 1 to 13 wherein the seat is concentric about the longitudinal axis.

15. The fluid flow component of any one of claims 1 to 14 wherein the closure member moves within the cavity of the housing in a direction parallel to the longitudinal axis.

16. The fluid flow component of any one of claims 1 to 15 further comprising a stop member, the stop member aligned with the longitudinal axis.

17. The fluid flow component of claim 16 wherein the stop member comprises a first magnet.

18. The fluid flow component of claim 16 or claim 17 wherein the stop member is symmetric about the longitudinal axis.

19. The fluid flow component of any one of claims 16 to 18 wherein the stop member limits motion of the closure member along the longitudinal axis.

20. The fluid flow component of any one of claims 16 to 19 wherein the stop member is secured to the housing.

21. The fluid flow component of any one of claims 16 to 20 wherein the stop member is formed by a portion of the housing.

22. The fluid flow component of any one of claims 1 to 15 wherein the housing comprises a first pocket, a second pocket, and a third pocket, a first magnet within the first pocket, a third magnet within the second pocket, and a fourth magnet within the third pocket.

23. The fluid flow component of claim 22 wherein the closure member comprises a second magnet.

24. The fluid flow component of claim 23 wherein each of the first, second, third, and fourth magnets comprise a north pole and a south pole, each of the south poles of the first, second, third, and fourth magnets having the same orientation with respect to the longitudinal axis.

25. The fluid flow component of any one of claims 22 to 24 wherein the first, second, and third pockets are arranged at an equal distance from the longitudinal axis.

26. A system for processing articles, the system comprising:
a first fluid flow component, the fluid flow component comprising:
a housing comprising:
an inlet comprising a first port, the first port comprising a seal cavity;
an outlet comprising a second port, the second port comprising a seal cavity;
a cavity, a longitudinal axis extending along the cavity;
a seat within the cavity; and
a flow path extending from the inlet to the cavity and from the cavity to the outlet; and
a closure member slidably movable within the cavity of the housing, the closure member configured to engage the seat to prevent fluid flow through the flow path in a reverse direction; and
a second fluid flow component, the fluid flow component comprising a first port and a second port, a flow path extending from the first port to the second port, each of the first port and the second port comprising a seal cavity; and
a seal;
wherein the second port of the second fluid flow component is aligned with the first port of the first fluid flow component, the seal located within the seal cavity of the second port of the second fluid flow component and the seal cavity of the first port of the first fluid flow component; and
wherein a magnetic field biases the closure member into contact with the seat.

27. The system of claim 26 wherein the magnetic field is configured to repel the closure member.

28. The system of claim 26 or claim 27 further comprising a first magnet, the first magnet generating a first portion of the magnetic field.

29. The system of claim 28 wherein the first magnet is spaced and isolated from the closure member.

30. The system of claim 28 or claim 29 wherein the closure member comprises a second magnet.

31. The system of claim 30 wherein the second magnet generates a second portion of the magnetic field.

32. The system of claim 31 wherein the first portion of the magnetic field comprises a first plurality of field lines and the second portion of the magnetic field comprises a second plurality of field lines, the first plurality of field lines spaced and isolated from the second plurality of field lines.

33. The system of any one of claims 26 to 32 wherein the closure member comprises a cavity, a second magnet located within the cavity of the closure member.

34. The system of claim 33 wherein the closure member further comprises a sealing element which seals the cavity of the closure member.

35. The system of any one of claims 26 to 34 wherein the cavity of the housing comprises an inner surface and the closure member comprises a plurality of protuberances, the plurality of protuberances engaging the inner surface.

36. The system of claim 35 wherein the inner surface of the cavity of the housing has a constant diameter with respect to the longitudinal axis.

37. The system of claim 35 or claim 36 wherein the plurality of protuberances prevent lateral movement of the closure member with respect to the longitudinal axis.

38. The system of any one of claims 26 to 37 wherein the first fluid flow component is free of mechanical biasing elements.

39. The system of any one of claims 26 to 38 wherein the seat is concentric about the longitudinal axis.

40. The system of claim 39 wherein the closure member moves within the cavity of the housing in a direction parallel to the longitudinal axis.

41. The system of any one of claims 26 to 15 wherein the first fluid flow component further comprises a stop member, the stop member aligned with the longitudinal axis.

42. The system of claim 41 wherein the stop member comprises a first magnet.

43. The system of claim 41 or claim 42 wherein the stop member is symmetric about the longitudinal axis.

44. The system of any one of claims 41 to 43 wherein the stop member limits motion of the closure member along the longitudinal axis.

45. The system of any one of claims 41 to 44 wherein the stop member is secured to the housing.

46. The system of any one of claims 41 to 45 wherein the stop member is formed by a portion of the housing.

47. The system of any one of claims 26 to 46 wherein the housing comprises a first pocket, a second pocket, and a third pocket, a first magnet within the first pocket, a third magnet within the second pocket, and a fourth magnet within the third pocket.

48. The system of claim 47 wherein the closure member comprises a second magnet.

49. The system of claim 48 wherein each of the first, second, third, and fourth magnets comprise a north pole and a south pole, each of the south poles of the first, second, third, and fourth magnets having the same orientation with respect to the longitudinal axis.

50. The system of any one of claims 47 to 49 wherein the first, second, and third pockets are arranged at an equal distance from the longitudinal axis.

51. A fluid flow component, the fluid flow component comprising:
a housing comprising:
an inlet;
an outlet;
a cavity, a longitudinal axis extending along the cavity;
a seat within the cavity; and
a flow path extending from the inlet to the cavity and from the cavity to the outlet;
a stop member comprising a first magnet; and
a closure member slidably movable within the cavity of the housing, the closure member comprising a second magnet, the closure member configured to engage the seat to prevent fluid flow through the flow path in a reverse direction; and
wherein a magnetic field generated by the first and second magnets biases the closure member into contact with the seat.

52. The fluid flow component of claim 51 wherein the magnetic field is configured to repel the closure member.

53. The fluid flow component of claim 51 or claim 52 wherein the first magnet generates a first portion of the magnetic field.

54. The fluid flow component of any one of claims 51 to 53 wherein the first magnet is spaced and isolated from the closure member.

55. The fluid flow component of any one of claims 51 to 54 wherein the second magnet generates a second portion of the magnetic field.

56. The fluid flow component of any one of claims 51 to 55 wherein a first portion of the magnetic field comprises a first plurality of field lines and a second portion of the magnetic field comprises a second plurality of field lines, the first plurality of field lines spaced and isolated from the second plurality of field lines.

57. The fluid flow component of any one of claims 51 to 57 wherein the closure member comprises a cavity, the second magnet located within the cavity of the closure member.

58. The fluid flow component of claim 57 wherein the closure member further comprises a sealing element which seals the cavity of the closure member.

59. The fluid flow component of any one of claims 51 to 58 wherein the cavity of the housing comprises an inner surface and the closure member comprises a plurality of protuberances, the plurality of protuberances engaging the inner surface.

60. The fluid flow component of claim 59 wherein the inner surface of the cavity of the housing has a constant diameter with respect to the longitudinal axis.

61. The fluid flow component of claim 59 or claim 60 wherein the plurality of protuberances prevent lateral movement of the closure member with respect to the longitudinal axis.

62. The fluid flow component of any one of claims 51 to 61 wherein the fluid flow component is free of mechanical biasing elements.

63. The fluid flow component of any one of claims 51 to 62 wherein the seat is concentric about the longitudinal axis.

64. The fluid flow component of claim 63 wherein the closure member moves within the cavity of the housing in a direction parallel to the longitudinal axis.

65. The fluid flow component of any one of claims 51 to 64 wherein the stop member is aligned with the longitudinal axis.

66. The fluid flow component of claim 65 wherein the stop member is symmetric about the longitudinal axis.

67. The fluid flow component of claim 65 or claim 66 wherein the stop member limits motion of the closure member along the longitudinal axis.

68. The fluid flow component of any one of claims 65 to 67 wherein the stop member is secured to the housing.

69. The fluid flow component of any one of claims 65 to 68 wherein the stop member is formed by a portion of the housing.

70. The fluid flow component of any one of claims 51 to 69 wherein the housing comprises a first pocket, a second pocket, and a third pocket, a first magnet within the first pocket, a third magnet within the second pocket, and a fourth magnet within the third pocket.

71. The fluid flow component of claim 70 wherein each of the first, second, third, and fourth magnets comprise a north pole and a south pole, each of the south poles of the first, second, third, and fourth magnets having the same orientation with respect to the longitudinal axis.

72. The fluid flow component of claim 70 or claim 71 wherein the first, second, and third pockets are arranged at an equal distance from the longitudinal axis.

73. A closure member for a check valve comprising:
a body extending from a first end to a second end along a longitudinal axis, the body having a cavity formed therein;
an enlarged portion formed at the first end of the body, the enlarged portion comprising a sealing surface;
a shaft portion extending from the enlarged portion to the second end;
a plurality of protuberances extending from the shaft portion; and
a magnet located within the cavity.

74. The closure member of claim 73 wherein each of the plurality of protuberances has an arcuate outer portion.

75. The closure member of claim 74 wherein the plurality of protuberances form portions of a first annular ring and a second annular ring.

76. The closure member of any one of claims 73 to 75 wherein the cavity is formed into the enlarged portion of the body.

77. The closure member of any one of claims 73 to 76 wherein adjacent ones of the plurality of protuberances are separated by gaps.

78. The closure member of any one of claims 73 to 77 wherein the plurality of protuberances collectively define an outer diameter which is greater than an outer diameter of the enlarged portion.

79. The closure member of any one of claims 73 to 78 wherein the enlarged portion comprises a recess, the sealing surface surrounding the recess.

80. The closure member of any one of claims 73 to 79 wherein the cavity is formed into the recess and extends into the shaft portion.

81. The closure member of claim 73 wherein the plurality of protuberances are fins.

82. The closure member of claim 81 wherein the plurality of protuberances are elongate with respect to the longitudinal axis.

83. The closure member of claim 81 or claim 82 wherein the plurality of protuberances extend from the enlarged portion of the body.

84. The closure member of claim 81 or claim 82 wherein the plurality of protuberances are spaced and isolated from the enlarged portion.

85. The closure member of any one of claims 81 to 84 wherein the plurality of protuberances collectively define an outer diameter which is equal to an outer diameter of the enlarged portion.

86. A closure member for a check valve comprising:
a body extending from a first end to a second end along a longitudinal axis;
a first portion formed at the first end of the body comprising a sealing surface;
a plurality of protuberances extending from the first portion along the longitudinal axis, the plurality of protuberances defining a cavity; and
a magnet located within the cavity.

87. The closure member of claim 86 wherein the plurality of protuberances have a first outer diameter and the first portion has a second outer diameter, the first outer diameter greater than the second outer diameter.

88. The closure member of claim 86 or claim 87 wherein the plurality of protuberances collectively define a cylinder.

89. The closure member of any one of claims 86 to 88 wherein the plurality of protuberances are elongate with respect to the longitudinal axis.

90. The closure member of any one of claims 86 to 89 wherein each of the plurality of protuberances comprises a groove, the groove configured to engage a protuberance of the magnet.

91. The closure member of any one of claims 86 to 90 wherein the cavity is open at the second end of the body.

92. The closure member of any one of claims 86 to 91 wherein the cavity is open between adjacent ones of the plurality of protuberances.
